(19) United States
(12) Patent Application Publication
(10) Pub. No.: US 2025/0393202 A1
(43) Pub. Date: Dec. 25, 2025

(54) SEMICONDUCTOR MEMORY DEVICE

(71) Applicant: Samsung Electronics Co., Ltd., Suwon-si (KR)

(72) Inventor: Moon Ju HONG, Suwon-si (KR)

(21) Appl. No.: 19/007,793

(22) Filed: Jan. 2, 2025

(30) Foreign Application Priority Data
Jun. 19, 2024 (KR) 10-2024-0079747

(51) Int. Cl. H10B 12/00

(52) U.S. Cl. CPC H10B 12/50; H10B 12/09; H10B 12/315

(57) ABSTRACT

A semiconductor memory device includes a peripheral gate structure on a substrate, a cell lower insulating layer on the peripheral gate structure, a bit line in the cell lower insulating layer and extended in a first direction, a mold insulating structure layer on the bit line and the cell lower insulating layer, including a channel trench extended in a second direction crossing the first direction, a channel structure in the channel trench and electrically connected to an upper surface of the bit line, including a metal oxide, a first word line on the channel structure and extended in the second direction, a second word line on the channel structure, extended in the second direction and spaced apart from the first word line in the first direction, a cutting pattern that contacts an end of each of the first and second word lines and extended in the first direction, a passage pattern in the mold insulating structure layer and including an oxide-based insulating material, a pad isolation pattern on the mold insulating layer and the passage pattern and connected to the passage pattern, a landing pad disposed in the pad isolation pattern and electrically connected to the channel structure, and a data storage pattern on the landing pad.

### CROSS-REFERENCE TO RELATED APPLICATION

This application claims priority from Korean Patent Application No. 10-2024-0079747, filed on Jun. 19, 2024, in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor memory device, and more particularly, to a semiconductor memory device that includes a vertical channel transistor (VCT).

### Description of the Related Art

The degree of integration of a semiconductor memory device may be increased to meet excellent performance and low price, which are desired by consumers. Because the degree of integration of the semiconductor memory device is a factor that is used to determine the price of a product, an increased degree of integration may be particularly desirable.

In case of a two-dimensional or planar semiconductor memory device, because the degree of integration of the two-dimensional or planar semiconductor memory device is mainly determined by an area occupied by a unit memory cell, the two-dimensional or planar semiconductor memory device may be greatly affected by a level of technology for forming a fine pattern. However, because ultra-high-priced equipment is generally required for pattern miniaturization, the degree of integration of the two-dimensional semiconductor memory device is increasing but still limited. Accordingly, semiconductor memory devices that include a vertical channel transistor of which the channel is extended in a vertical direction have been proposed.

### SUMMARY

An object of the present disclosure is to provide a semiconductor memory device in which the degree of integration and electrical characteristics are improved.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a semiconductor memory device comprising a peripheral gate structure on a substrate, a cell lower insulating layer on the peripheral gate structure, a bit line in the cell lower insulating layer and extended in a first direction, a mold insulating structure layer on the bit line and the cell lower insulating layer, including a channel trench extended in a second direction crossing the first direction, a channel structure in the channel trench and electrically connected to an upper surface of the bit line, including a metal oxide, a first word line on the channel structure and extended in the second direction, a second word line on the channel structure, extended in the second direction and spaced apart from the first word line in the first direction, a cutting pattern that contacts an end of each of the first and second word lines and extended in the first direction, a passage pattern in the mold insulating structure layer and including an oxide-based insulating material, a pad isolation pattern on the mold insulating layer and the passage pattern and connected to the passage pattern, a landing pad in the pad isolation pattern and electrically connected to the channel structure, and a data storage pattern disposed on the landing pad.

According to another aspect of the present disclosure, there is provided a semiconductor memory device comprising a peripheral gate structure on a substrate, a cell lower insulating layer on the peripheral gate structure, a bit line in the cell lower insulating layer and extended in a first direction, a mold insulating structure layer on the bit line and the cell lower insulating layer, including a channel trench extended in a second direction crossing the first direction, a channel structure in the channel trench and electrically connected to an upper surface of the bit line, that channel structure including a metal oxide, a first word line on the channel structure and extended in the second direction, a second word line on the channel structure, extended in the second direction and spaced apart from the first word line in the first direction, a contact isolation pattern on the mold insulating structure layer, a contact pattern in the contact isolation pattern and electrically connected to the channel structure, a pad isolation pattern on the contact isolation pattern and the contact pattern, a landing pad in the pad isolation pattern and electrically connected to the contact pattern, a passage pattern extended in a third direction crossing the first and second directions, passing through the contact isolation pattern and the pad isolation pattern, a cutting pattern contacting an end of each of the first and second word lines, extended in the first direction, an upper etching stop film on the landing pad and the pad isolation pattern, at least partially covering an upper surface of the passage pattern, and a data storage pattern on the upper etching stop film and connected to the landing pad.

According to still another aspect of the present disclosure, there is provided a semiconductor memory device comprising a peripheral gate structure on a substrate, a cell lower insulating layer on the peripheral gate structure, a plurality of bit lines in the cell lower insulating layer, extended in a first direction and arranged in a second direction crossing the first direction, a mold insulating structure layer on the plurality of bit lines and the cell lower insulating layer, including a channel trench extended in the second direction, a channel structure in the channel trench and electrically connected to an upper surface of the plurality of bit lines, containing metal oxide, a first word line on the channel structure and extended in the second direction, a second word line on the channel structure, extended in the second direction and spaced apart from the first word line in the first direction, a passage pattern between the respective bit lines adjacent to each other in the second direction and in the mold insulating structure layer, a cutting pattern that contacts an end of each of the first and second word lines, extended in the first direction, a landing pad on the channel structure and electrically connected to the channel structure, an upper etching stop film on the landing pad and at least partially covering an upper surface of the passage pattern, and a data storage pattern on the upper etching stop film and electrically connected to the landing pad.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic perspective view illustrating a semiconductor memory device according to some embodiments.

FIG. 2 is a layout view illustrating a semiconductor memory device according to some embodiments.

FIGS. 3 to 5 are views illustrating a semiconductor memory device according to some embodiments.

FIGS. 6 and 7 are views illustrating a semiconductor memory device according to some embodiments.

FIGS. 8 and 9 are views illustrating a semiconductor memory device according to some embodiments.

FIGS. 10 and 11 are views illustrating a semiconductor memory device according to some embodiments.

FIGS. 12 and 13 are views illustrating a semiconductor memory device according to some embodiments.

FIGS. 14 and 15 are views illustrating a semiconductor memory device according to some embodiments.

FIGS. 16 and 17 are views illustrating a semiconductor memory device according to some embodiments.

FIGS. 18 and 19 are views illustrating a semiconductor memory device according to some embodiments.

FIGS. 20 to 40 are views illustrating intermediate operations of a method for fabricating a semiconductor memory device according to some embodiments.

FIGS. 41 to 50 are views illustrating intermediate operations of a method for fabricating a semiconductor memory device according to some embodiments.

### DETAILED DESCRIPTION OF THE DISCLOSURE

Hereinafter, example embodiments of the present disclosure will be described in more detail with reference to the attached drawings. The same reference numerals are used for the same components in the drawings, and duplicate descriptions for the same components are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

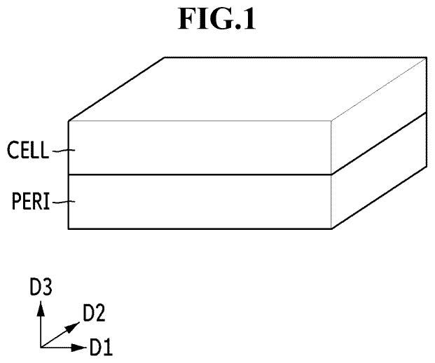

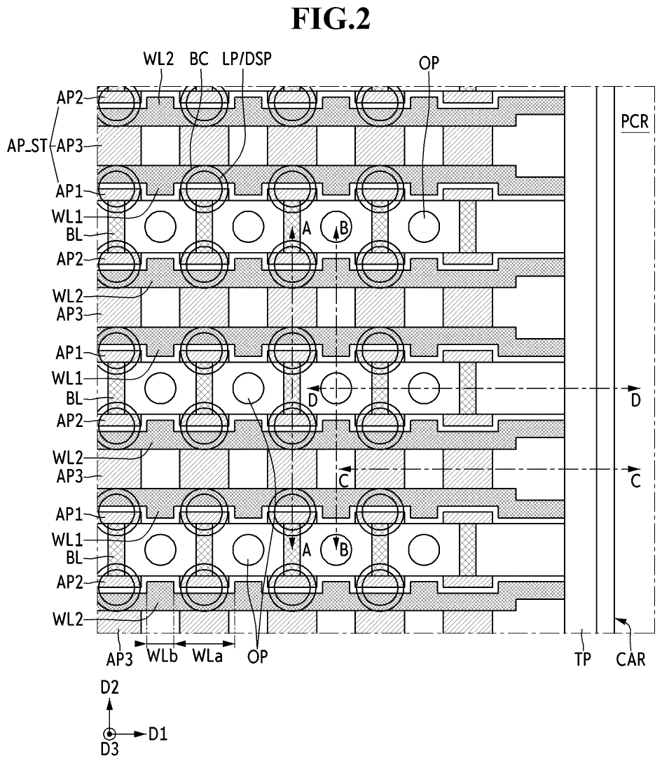

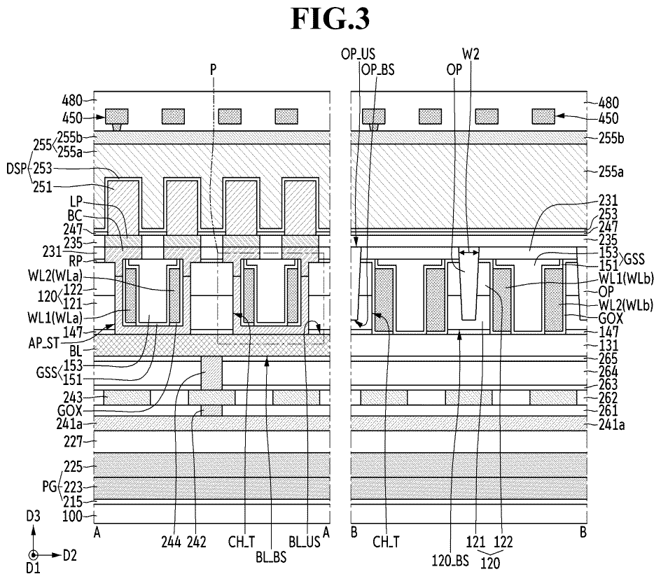

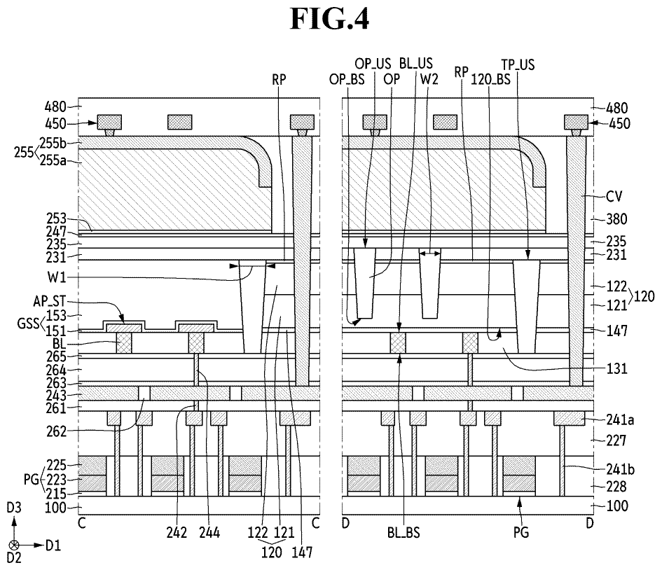

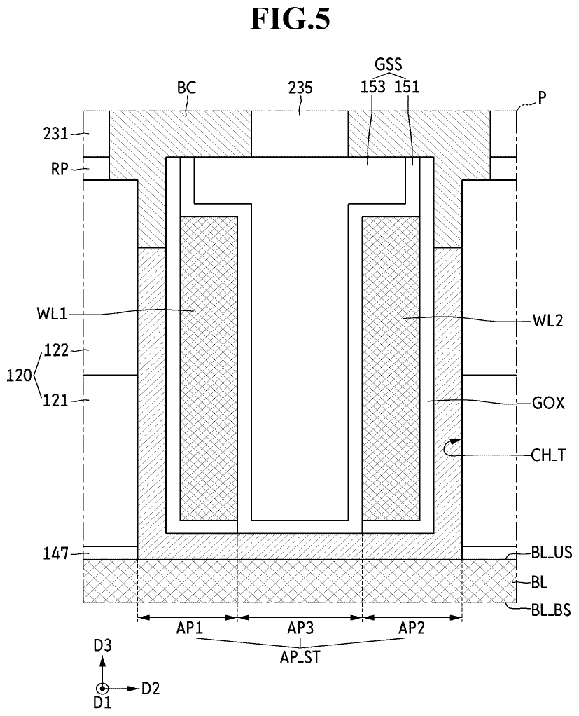

FIG. 1 is a schematic perspective view illustrating a semiconductor memory device according to some embodiments. FIG. 2 is a layout view illustrating a semiconductor memory device according to some embodiments. FIGS. 3 to 5 are views illustrating a semiconductor memory device according to some embodiments. For reference, FIG. 3 is a cross-sectional view taken along lines A-A and B-B of FIG. 2, and FIG. 4 is a cross-sectional view taken along lines C-C and D-D of FIG. 2. Also, for reference, FIG. 5 is an enlarged view illustrating a portion P of FIG. 3.

A semiconductor memory device according to some embodiments may include memory cells that include a vertical channel transistor (VCT).

Referring to FIG. 1, the semiconductor memory device according to some embodiments of the present disclosure may include a peripheral gate structure PERI and a cell structure CELL.

The peripheral circuit structure PERI and the cell structure CELL may be stacked in a third direction D3. The cell structure CELL may be disposed on an upper portion of the peripheral circuit structure PERI. In the present disclosure, a first direction D1, a second direction D2 and the third direction D3 may cross one another. The first direction D1, the second direction D2 and the third direction D3 may be substantially perpendicular to one another.

The semiconductor memory device according to some embodiments may have a chip to chip (C2C) structure. The C2C structure means that an upper chip including the memory cell structure CELL is manufactured on a first wafer, a lower chip (e.g., the peripheral circuit structure PERI) is manufactured on a second wafer different from the first wafer, and then the upper chip and the lower chip are connected to each other by a bonding method.

Referring to FIGS. 2 to 5, the semiconductor memory device according to some embodiments may include a substrate 100, a peripheral gate structure PG, bit lines BL, first and second word lines WL1 and WL2, channel structures AP_ST, mold insulating structure layers 120, passage patterns OP, a cutting pattern TP, and information storage patterns DSP.

The substrate 100 may include a cell array region CAR and a peripheral circuit region PCR. Memory cells may be disposed on the substrate 100 of the cell array region CAR.

The substrate 100 may be a silicon substrate, and/or may include another material, such as silicon germanium, indium antimonide, lead telluride, indium arsenide, indium phosphide, gallium arsenide or gallium antimonide, but embodiments are not limited thereto.

The peripheral gate structure PG may be disposed on the substrate 100. The peripheral gate structure PG may be disposed over the cell array region CAR and the peripheral circuit region PCR. In other words, a portion of the peripheral gate structure PG may be disposed in the cell array region CAR of the substrate 100, and the rest of the peripheral gate structure PG may be disposed in the peripheral circuit region PCR of the substrate 100.

The peripheral gate structure PG may include a sensing transistor, a transfer transistor, and a driving transistor. The types of transistors disposed in the cell array region CAR and the peripheral circuit region PCR may be varied depending on a design arrangement of the semiconductor memory device.

The peripheral gate structure PG may include a peripheral gate insulating film 215, a peripheral lower conductive pattern 223 and a peripheral upper conductive pattern 225. The peripheral gate insulating film 215 may include a silicon oxide film, a silicon oxynitride film, a high dielectric constant insulating film having a dielectric constant higher than that of the silicon oxide film, or their combination. The high dielectric constant insulating film may include at least one of, for example, metal oxide, metal oxynitride, metal silicon oxide and/or metal silicon oxynitride, but embodiments are not limited thereto.

Each of the peripheral lower conductive pattern 223 and the peripheral upper conductive pattern 225 may contain a conductive material. For example, each of the peripheral lower conductive pattern 223 and the peripheral upper conductive pattern 225 may contain at least one of a doped semiconductor material, a conductive metal nitride, a conductive metal silicon nitride, a metal carbonitride, a conductive metal silicide, a conductive metal oxide, a two-dimensional (2D) material, metal and/or a metal alloy. The peripheral gate structure PG is shown as including a plurality of conductive patterns, but embodiments are not limited thereto.

In the semiconductor memory device according to some embodiments, the two-dimensional material may be a metallic material and/or a semiconductor material. The two-dimensional (2D) material may contain a two-dimensional allotrope or a two-dimensional compound, and may contain at least one of, for example, graphene, molybdenum disulfide (MoS₂), molybdenum diselenide (MoSe₂), tungsten diselenide (WSe₂), and/or tungsten disulfide (WS₂), but embodiments are not limited thereto. That is, because the two-dimensional materials described above are only examples, the two-dimensional material that may be contained in the semiconductor memory device of the present disclosure is not limited by the above-described materials.

A first peripheral lower insulating layer 227 and a second peripheral lower insulating layer 228 are disposed on the substrate 100. Each of the first peripheral lower insulating layer 227 and the second peripheral lower insulating layer 228 may be made of or may comprise an insulating material.

A first peripheral wiring line 241a and a peripheral contact plug 241b may be disposed in the first peripheral lower insulating layer 227 and the second peripheral lower insulating layer 228. The first peripheral wiring line 241a and the peripheral contact plug 241b are shown as being films different from each other, but embodiments are not limited thereto. A boundary between the first peripheral wiring line 241a and the peripheral contact plug 241b may not be distinguished. Each of the first peripheral wiring line 241a and the peripheral contact plug 241b may contain or may comprise a conductive material.

The first peripheral wiring line 241a and the peripheral contact plug 241b may be disposed on the substrate 100 of the peripheral circuit region PCR.

A first peripheral upper insulating layer 261 and a second peripheral upper insulating layer 262 may be disposed on the first peripheral wiring line 241a and the peripheral contact plug 241b. Each of the first peripheral upper insulating layer 261 and the second peripheral upper insulating layer 262 may be made of or may comprise an insulating material.

A second peripheral wiring line 243 and a peripheral via plug 242 are disposed on the first peripheral wiring line 241a. The second peripheral wiring line 243 and the peripheral via plug 242 may be disposed on the substrate 100 of the peripheral circuit region PCR. The second peripheral wiring line 243 disposed on the substrate 100 of the peripheral circuit region PCR may be directly connected to a contact via CV that will be described below.

The peripheral via plug 242 may be disposed in the first peripheral upper insulating layer 261. The second peripheral wiring line 243 may be disposed in the second peripheral upper insulating layer 262.

The second peripheral wiring line 243 and the peripheral via plug 242 may be electrically connected to the first peripheral wiring line 241a. The peripheral via plug 242 may electrically connect the first peripheral wiring line 241a with the second peripheral wiring line 243. Each of the second peripheral wiring line 243 and the peripheral via plug 242 contain or may comprise a conductive material. The second peripheral wiring line 243 and the peripheral via plug 242 are shown as films different from each other, but embodiments are not limited thereto. A boundary between the second peripheral wiring line 243 and the peripheral via plug 242 may not be distinguished.

A third peripheral upper insulating layer 263, a fourth peripheral upper insulating layer 264 and a fifth peripheral upper insulating layer 265 may be sequentially disposed on the second peripheral wiring line 243. Each of the third peripheral upper insulating layer 263, the fourth peripheral upper insulating layer 264 and the fifth peripheral upper insulating layer 265 may be made of or may comprise an insulating material.

The fourth peripheral upper insulating layer 264 may be made of or may comprise an insulating material different from that of the third peripheral upper insulating layer 263 and the fifth peripheral upper insulating layer 265. For example, the fourth peripheral upper insulating layer 264 may be made of or may comprise an oxide-based insulating material, and the third peripheral upper insulating layer 263 and the fifth peripheral upper insulating layer 265 may be made of or may comprise a nitride-based insulating material, but embodiments of the present disclosure are not limited thereto.

A cell connection plug 244 may be disposed in the third peripheral upper insulating layer 263, the fourth peripheral upper insulating layer 264 and the fifth peripheral upper insulating layer 265. The cell connection plug 244 may be connected to the second peripheral wiring line 243. The cell connection plug 244 contain or may comprise a conductive material. Unlike the shown example, the cell connection plug 244 may be disposed in the peripheral upper insulating layers 261, 262, 263, 264 and 265 made of a single layer.

The bit lines BL may be disposed on the peripheral gate structure PG. In more detail, the bit lines BL may be disposed on the fifth peripheral upper insulating layer 265. For example, the bit lines BL may be in contact with the fifth peripheral upper insulating layer 265.

The bit lines BL may include an upper surface BL_US and a bottom surface BL_BS, which are opposite to each other in the third direction D3. The bottom surface BL_BS of the bit line BL may face the substrate 100.

The bit line BL may be extended lengthwise in the second direction D2. The bit lines BL adjacent to each other may be spaced apart from each other in the first direction D1. The bit line BL includes a long sidewall extended in the second direction D2 and a short sidewall extended in the first direction D1.

Although not shown, each bit line BL may be extended from the cell array region CAR to the peripheral circuit region PCR. An end portion of each bit line BL may be disposed on the peripheral circuit region PCR of the substrate 100.

Each bit line BL may be disposed on the cell connection plug 244. Each bit line BL may be electrically connected to the cell connection plug 244. Each bit line BL may contain or may comprise at least one of, for example, a doped semiconductor material, a conductive metal nitride, a conductive metal silicon nitride, a metal carbonitride, a conductive metal silicide, a conductive metal oxide, a two-dimensional material, metal, and/or a metal alloy. Each bit line BL is shown as a single layer, but embodiments are not limited thereto.

A cell lower insulating layer 131 may be disposed on the peripheral gate structure PG. In detail, the cell lower insulating layer 131 may be disposed on the fifth peripheral upper insulating layer 265. The cell lower insulating layer 131 is disposed between the bit lines BL spaced apart from each other in the first direction D1. That is, the bit line BL may be disposed in the cell lower insulating layer 131. The cell lower insulating layer 131 may be made of or may comprise an insulating material. For example, the cell lower insulating layer 131 may contain an oxide-based insulating material.

The mold insulating structure layer 120 may be disposed on the bit line BL and the cell lower insulating layer 131. The mold insulating structure layer 120 may be disposed over the cell array region CAR and the peripheral circuit region PCR.

A lower etching stop film 147 may be disposed between the mold insulating structure layer 120 and the cell lower insulating layer 131. The lower etching stop film 147 may be disposed between the mold insulating structure layer 120 and the bit line BL. In other words, the bottom surface 120_BS of the mold insulating structure layer 120 may be in contact with the lower etching stop film 147. The lower etching stop film 147 may be disposed over the cell array region CAR and the peripheral circuit region PCR.

The mold insulating structure layer 120 may include a first mold insulating layer 121 and a second mold insulating layer 122.

The first mold insulating layer 121 and the second mold insulating layer 122 may be sequentially disposed on the bit line BL and the cell lower insulating layer 131. The second mold insulating layer 122 may be disposed on the first mold insulating layer 121. For example, the first mold insulating layer 121 may be disposed between the bit line BL and the cell lower insulating layer 131 and the second mold insulating layer 122. The first mold insulating layer 121 and the second mold insulating layer 122 may be extended in the first direction D1.

The first mold insulating layer 121 may be disposed on the lower etching stop film 147. For example, the lower etching stop film 147 may be disposed between the first mold insulating layer 121 and the bit line BL and the cell lower insulating layer 131. In other words, a bottom surface of the first mold insulating layer 121 may be in contact with the lower etching stop film 147. That is, a bottom surface 120_BS of the mold insulating structure layer 120 may be the bottom surface of the first mold insulating layer 121.

Each of the mold insulating structure layer 120 and the lower etching stop film 147 may be made of an insulating material. The first mold insulating layer 121 and the second mold insulating layer 122 may contain or may comprise one or more respective materials that are different from each other. The first mold insulating layer 121 may contain or may comprise a silicon oxide-based insulating material, for example, silicon oxide. The second mold insulating layer 122 may contain or may comprise a silicon nitride-based insulating material, for example, silicon nitride. The lower etching stop film 147 may include a material having etching selectivity with respect to the mold insulating structure layer 120. For example, the lower etching stop film 147 may contain or may comprise an insulating material having etching selectivity with respect to the first mold insulating layer 121.

The mold insulating structure layer 120 may be in contact with the passage pattern OP that will be described later. The passage pattern OP may pass through the inside of the mold insulating structure layer 120. The mold insulating structure layer 120 may be in contact with the cutting pattern TP that will be described below. The cutting pattern TP may pass through the inside of the mold insulating structure layer 120.

The mold insulating structure layer 120 may include a plurality of channel trenches CH_T. Each of the channel trenches CH_T may be extended lengthwise in the first direction D1. The channel trenches CH_T adjacent to each other may be spaced apart from each other in the second direction D2. Each of the channel trenches CH_T crosses the bit line BL. One channel trench CH_T may at least partially expose the bit lines BL adjacent to each other in the first direction D1.

A bottom surface of each of the channel trenches CH_T may be defined by the bit line BL and the cell lower insulating layer 131. Sidewalls of each channel trench CH_T may be defined by sidewalls of the mold insulating structure layer 120 and sidewalls of the lower etching stop film 147.

The channel structure AP_ST may be disposed on each bit line BL. The plurality of channel structures AP_ST may be connected to one bit line BL. The plurality of channel structures AP_ST disposed on one bit line BL may be spaced apart from each other in the second direction D2.

The channel structure AP_ST may be disposed inside the channel trench CH_T extended in the first direction D1. The plurality of channel structures AP_ST may be disposed inside one channel trench CH_T. The plurality of channel structures AP_ST disposed inside the channel trench CH_T may be spaced apart from each other in the first direction D1.

For example, the channel structures AP_ST may be two-dimensionally disposed along the first direction D1 and the second direction D2.

The channel structure AP_ST may include a first channel pattern AP1, a second channel pattern AP2, and a third channel pattern AP3. The third channel pattern AP3 may electrically connect the first channel pattern AP1 with the second channel pattern AP2. The first channel pattern AP1 and the second channel pattern AP2 may be spaced apart from each other in the second direction D2.

The first channel pattern AP1, the second channel pattern AP2, and the third channel pattern AP3 may be disposed on the bit line BL. The first channel pattern AP1, the second channel pattern AP2, and the third channel pattern AP3 may be electrically connected to the bit line BL. The first channel pattern AP1, the second channel pattern AP2 and the third channel pattern AP3 may be in contact with the upper surface BL_US of the bit line BL.

The channel structure AP_ST may be extended along the sidewalls and a bottom surface of the channel trench CH_T. In a cross-sectional view as shown in FIG. 3, the channel structure AP_ST may have a “U” shape. For example, the third channel pattern AP3 may be extended along the bottom surface of the channel trench CH_T, and the first channel pattern AP1 and the second channel pattern AP2 may be extended along a portion of the bottom surface of the channel trench CH_T and the sidewalls of the channel trench CH_T.

The channel structure AP_ST may include a first channel structure AP_ST and a second channel structure AP_ST, which are adjacent to each other in the second direction D2. The mold insulating structure layer 120 may be disposed between the first channel structure AP_ST and the second channel structure AP_ST, which are adjacent to each other in the second direction D2.

For example, the mold insulating structure layer 120 may be disposed between the first channel pattern AP1 of the first channel structure AP_ST and the second channel pattern AP2 of the second channel structure AP_ST.

In the semiconductor memory device according to some embodiments, the channel structure AP_ST may contain an oxide semiconductor material. The channel structure AP_ST may contain or may comprise, for example, indium gallium zinc oxide (IGZO), indium zinc oxide (IZO) doped with impurities, indium oxide (InO), zinc oxide (ZnO), gallium oxide (GaO), tin oxide (SnO), aluminum zinc oxide (AZO) and indium tin oxide (ITO). In indium zinc oxide (IZO) doped with impurities, the doped impurities may contain, for example, at least one of magnesium (Mg), strontium (Sr), barium (Ba), scandium (Sc), yttrium (Y), lanthanum (La), titanium (Ti), zirconium (Zr), hafnium (Al), aluminum (Al), tin (Sn), and/or tantalum (Ta).

Indium gallium zinc oxide (IGZO) contained in the channel structure AP_ST may be Ga-rich IGZO, In-rich IGZO or IGZO (In:Ga:Zn=1:1:1). Ga-rich IGZO may have a higher gallium ratio than IGZO (In:Ga:Zn=1:1:1), and may have a lower indium ratio than IGZO (In:Ga:Zn=1:1:1). In-rich IGZO may have a higher indium ratio than IGZO (In:Ga:Zn=1:1:1), and may have a lower gallium ratio than IGZO (In:Ga:Zn=1:1:1). However, the materials contained in the channel structure AP_ST are not limited to the above examples.

The first word line WL1 and the second word line WL2 may be disposed on the channel structure AP_ST. The first word line WL1 and the second word line WL2 may be disposed in the channel trench CH_T.

Each of the first word line WL1 and the second word line WL2 may be extended in the first direction D1. The first word line WL1 and the second word line WL2 may be alternately arranged in the second direction D2. The first word line WL1 and the second word line WL2 may be spaced apart from each other in the second direction D2.

The first word line WL1 and the second word line WL2 may be spaced apart from the bit line BL in the third direction D3. The first word line WL1 and the second word line WL2 may cross the bit line BL.

The first word line WL1 and the second word line WL2 may be disposed on the first channel pattern AP1 and the second channel pattern AP2, respectively.

The first word line WL1 may include an inner wall facing the mold insulating structure layer 120, and an outer wall opposite to the inner wall in the second direction D2. A boundary between the first channel pattern AP1 and the third channel pattern AP3 may be an extension line in which the outer wall of the first word line WL1 is extended in the third direction D3.

The second word line WL2 may include an inner wall facing the mold insulating structure layer 120, and an outer wall opposite to the inner wall in the second direction D2. A boundary between the second channel pattern AP2 and the third channel pattern AP3 may be an extension line in which the outer wall of the second word line WL2 is extended in the third direction D3.

The first word line WL1 and the second word line WL2 may be disposed between the first channel pattern AP1 and the second channel pattern AP2. The first word line WL1 may be more adjacent or closer to the first channel pattern AP1 than the second channel pattern AP2. The second word line WL2 may be more adjacent or closer to the second channel pattern AP2 than the first channel pattern AP1.

Each of the first word line WL1 and the second word line WL2 may have a width in the second direction D2. The width of the first word line WL1 in the second direction D2 at a portion that overlaps the channel structure AP_ST in the second direction D2 may be different from the width of the first word line WL1 in the second direction D2 at a portion that does not overlap the channel structure AP_ST in the second direction D2. The width of the second word line WL2 in the second direction D2 at a portion that overlaps the channel structure AP_ST in the second direction D2 may be different from the width of the second word line WL2 in the second direction D2 at a portion that does not overlap the channel structure AP_ST in the second direction D2.

For example, each of the first word line WL1 and the second word line WL2 may include a first portion WLa of the word line and a second portion WLb of the word line. A width of the first portion WLa in the second direction D2 of the word line may be smaller than a width of the second portion WLb of the word line in the second direction D2.

The first portion WLa of the word line may be disposed on the channel structure AP_ST. In detail, the first word line WL1 disposed on the first channel pattern AP1 may be the first portion WLa of the word line WL1. The second word line WL2 disposed on the second channel pattern AP2 may be the first portion WLa of the word line WL2.

Each of the first word line WL1 and the second word line WL2 may include a first portion WLa of the word line and a second portion WLb of the word line, which are alternately disposed along the first direction D1. Each of the channel structures AP_ST may be disposed between the second portions WLb of the word lines, which are adjacent to each other in the first direction D1. In the first word line WL1, each of the first channel patterns AP1 may be disposed between the second portions WLb of the word lines, which are adjacent to each other in the first direction D1. In the second word line WL2, the second channel patterns AP2 may be disposed between the second portions WLb of the word lines, which are adjacent to each other in the second direction D2.

The second portion WLb of the word line may not be disposed on the channel structure AP_ST. A height of the first portion WLa of the word line in the third direction D3 may be smaller than a height of the second portion WLb of the word line in the third direction D3.

The first word line WL1 and the second word line WL2 contain a conductive material. For example, the first word line WL1 and the second word line WL2 may contain at least one of, for example, a doped polysilicon, a conductive metal nitride, a conductive metal silicon nitride, a metal carbonitride, a conductive metal silicide, a conductive metal oxide, a two-dimensional material, metal or a metal alloy.

A gate insulating film GOX may be disposed between the first word line WL1 and the channel structure AP_ST and between the second word line WL2 and the channel structure AP_ST. The gate insulating film GOX may be disposed between the first word line WL1 and the first channel pattern AP1 and between the second word line WL2 and the second channel pattern AP2. The gate insulating film GOX may be extended in the first direction D1 in parallel with the first word line WL1 and the second word line WL2.

The gate insulating film GOX may be extended in the third direction D3 between the first word line WL1 and the first channel pattern AP1. The gate insulating film GOX may be extended in the third direction D3 between the second word line WL2 and the second channel pattern AP2.

The gate insulating film GOX may be extended in the second direction D2 between the first word line WL1 and the first channel pattern AP1. The gate insulating film GOX may be extended in the second direction D2 between the second word line WL2 and the second channel pattern AP2. In the semiconductor memory device according to some embodiments, the gate insulating film GOX may not be disposed on the third channel pattern AP3. In a cross-sectional view as shown in FIG. 3, the gate insulating film GOX between the first word line WL1 and the first channel pattern AP1 may be separated from the gate insulating film GOX between the second word line WL2 and the second channel pattern AP2.

The gate insulating film GOX may include a silicon oxide film, a silicon oxynitride film, a high dielectric constant insulating film having a dielectric constant higher than that of the silicon oxide film, or any of their combinations. For example, the high dielectric constant insulating film may include aluminum oxide (Al₂O₃), but embodiments are not limited thereto.

A portion of the gate insulating film GOX may be more protruded in the third direction D3 than the uppermost portion of the channel structure AP_ST. A portion of the gate insulating film GOX may be more protruded in the third direction D3 than the uppermost portions of the first and second word lines WL1 and WL2. In this case, the uppermost portion refers to a portion at which a distance from the bottom surface BL_BS of the bit line BL in the third direction D3 is the farthest.

A residual insulating film RP may be disposed on the mold insulating structure layer 120. The residual insulating film RP may be disposed on the second mold insulating layer 122. The residual insulating film RP may be in contact with an upper surface of the second mold insulating layer 122. The residual insulating film RP may be disposed over the cell array region CAR and the peripheral circuit region PCR.

A height from the upper surface BL_US of the bit line BL to the uppermost portion of the residual insulating film RP may be the same as a height from the upper surface BL_US of the bit line BL to the uppermost portion of the gate insulating film GOX, but this is only an example and embodiments are not limited thereto.

The residual insulating film RP and the gate insulating film GOX may contain the same material. For example, the residual insulating film RP may include a silicon oxide film, a silicon oxynitride film, a high dielectric constant insulating film having a dielectric constant higher than that of the silicon oxide film, or any of their combinations.

In other words, the residual insulating film RP may be directly connected to the gate insulating film GOX to form one insulating liner. A portion of the insulating liner, which is disposed on the upper surface of the second mold insulating layer 122, may be the residual insulating film RP.

A gate isolation pattern GSS may be disposed on the bit line BL and the cell lower insulating layer 131. The gate isolation pattern GSS may be disposed in the channel trench CH_T. The gate isolation pattern GSS may be disposed on the channel structure AP_ST and the first and second word lines WL1 and WL2.

The gate isolation pattern GSS may be in contact with the channel structure AP_ST. The gate isolation pattern GSS may be disposed on the third channel pattern AP3. The gate isolation pattern GSS may be spaced apart from the bit line BL in the third direction D3.

The gate isolation pattern GSS may be disposed between the first word line WL1 and the second word line WL2, which are adjacent to each other in the second direction D2. The gate isolation pattern GSS may be in contact with the first word line WL1 and the second word line WL2. The first word line WL1 and the second word line WL2 may be separated from each other by the gate isolation pattern GSS. The gate isolation pattern GSS may be extended in the first direction D1 between the first word line WL1 and the second word line WL2.

The first word line WL1 may be disposed between the gate isolation pattern GSS and the channel structure AP_ST. The second word line WL2 may be disposed between the gate isolation pattern GSS and the channel structure AP_ST. The first word line WL1 may be disposed between the gate isolation pattern GSS and the first channel pattern AP1. The second word line WL2 may be disposed between the gate isolation pattern GSS and the second channel pattern AP2.

The gate isolation pattern GSS may include a horizontal portion and a protrusion portion. The protrusion portion of the gate isolation pattern GSS may be protruded in the third direction D3 from the horizontal portion of the gate isolation pattern GSS toward the bit line BL. The protrusion portion of the gate isolation pattern GSS may be closer to the bit line BL than the horizontal portion of the gate isolation pattern GSS. The protrusion portion of the gate isolation pattern GSS may be extended in the third direction D3 between the first word line WL1 and the second word line WL2. The protrusion portion of the gate isolation pattern GSS may be in contact with an upper surface of the third channel pattern AP3. The horizontal portion of the gate isolation pattern GSS may be disposed on upper surfaces of the first word line WL1 and the second word line WL2. When cut into a cross-section crossing the first direction D1, the gate isolation pattern GSS may have a “T” shape in the cross-section.

The gate isolation pattern GSS may include a gate isolation liner 151 and a gate isolation filling layer 153. The gate isolation liner 151 may be extended along the upper surface of the first word line WL1, the upper surface of the second word line WL2, an outer wall of the first word line WL1 and an outer wall of the second word line WL2. The gate isolation liner 151 may be extended along the third channel pattern AP3. The gate isolation liner 151 may be in contact with the third channel pattern AP3. The gate isolation liner 151 may be extended along the gate insulating film GOX that is more protruded than the upper surface of the first word line WL1 and the upper surface of the second word line WL2. A height from the upper surface BL_US of the bit line BL to the uppermost portion of the gate isolation liner 151 may be the same as the height from the upper surface BL_US of the bit line BL to the uppermost portion of the gate insulating film GOX, but embodiments are not limited thereto.

The gate isolation filling layer 153 may be disposed on the gate isolation liner 151. The gate isolation filling layer 153 may be in contact with the gate isolation liner 151. When cut into a cross-section crossing the first direction D1, the gate isolation filling layer 153 may have a “T” shape in the cross-section. A height from the upper surface BL_US of the bit line BL to the uppermost portion of the gate isolation filling layer 153 may be the same as the height from the upper surface BL_US of the bit line BL to the uppermost portion of the gate isolation liner 151, but embodiments are not limited thereto.

Based on the upper surface BL_US of the bit line BL, an upper surface of the gate isolation pattern GSS may be disposed at the same height in the D3 direction as an upper surface of the residual insulating film RP, but is not limited thereto.

Each of the gate isolation liner 151 and the gate isolation filling layer 153 may be made of an insulating material. Unlike the shown example, the gate isolation pattern GSS may be a single layer.

A height from the upper surface BL_US of the bit line BL to the uppermost portion of the gate isolation pattern GSS may be greater than a height from the upper surface BL_US of the bit line BL to the uppermost portion of the channel structure AP_ST. The height from the upper surface BL_US of the bit line BL to the uppermost portion of the gate isolation pattern GSS may be greater than a height from the upper surface BL_US of the bit line BL to the uppermost portions of the first and second word lines WL1 and WL2.

Contact patterns BC may be disposed on the channel structure AP_ST, the mold insulating layer 120, the gate isolation pattern GSS and the gate insulating film GOX.

The contact pattern BC may be disposed on the first channel pattern AP1, the second mold insulating layer 122, the gate isolation pattern GSS and the gate insulating film GOX. The contact pattern BC may be disposed on the second channel pattern AP2, the second mold insulating layer 122, the gate isolation pattern GSS and the gate insulating film GOX.

When viewed in a plan view, the contact pattern BC may have various shapes such as, but not limited to, a circular shape, an oval shape, a rectangular shape, a square shape, a rhombus shape and a hexagonal shape.

The contact pattern BC may be in contact with the first channel pattern AP1 and the second channel pattern AP2. The contact pattern BC may be electrically connected to the first channel pattern AP1 and the second channel pattern AP2.

The contact pattern BC may include a horizontal portion and a protrusion portion. The horizontal portion of the contact pattern BC may be disposed on the upper surface of the second mold insulating layer 122 and the uppermost portion of the gate isolation pattern GSS. The protrusion portion of the contact pattern BC may be protruded in the third direction D3 from the horizontal portion of the contact pattern BC toward the bit line BL. The protrusion portion of the contact pattern BC may be disposed between the second mold insulating layer 122 and the gate isolation pattern GSS. The protrusion portion of the contact pattern BC may be in contact with the channel structure AP_ST. The protrusion portion of the contact pattern BC may be in contact with a sidewall of the second mold insulating layer 122, a sidewall of the gate insulating film GOX, and a sidewall of the channel structure AP_ST.

The contact pattern BC may contain a conductive material. The contact pattern BC may contain at least one of, for example, a doped polysilicon, a conductive metal nitride, a conductive metal silicon nitride, a metal carbonitride, a conductive metal silicide, a conductive metal oxide, a two-dimensional material, metal, and/or a metal alloy.

The contact isolation pattern 231 may be disposed between the contact patterns BC. The contact isolation pattern 231 may at least partially fill a space between the contact patterns BC. When viewed in a plan view, the contact isolation pattern 231 may at least partially fill the space in which the contact patterns BC are arranged in the form of a matrix along the first and second directions D1 and D2.

The contact isolation pattern 231 may be disposed on the residual insulating film RP and the gate isolation pattern GSS. The contact isolation pattern 231 may be disposed on the cutting pattern TP that will be described below. The contact isolation pattern 231 may be disposed on the peripheral circuit region PCR.

The contact isolation pattern 231 may contain or may comprise an insulating material. The contact isolation pattern 231 may contain or may comprise a nitride-based insulating material, for example, silicon nitride.

Landing pads LP may be disposed on the contact pattern BC. The landing pads LP may be directly connected to the contact pattern BC.

When viewed in a plan view, the landing pads LP may have various shapes such as, but not limited to, a circular shape, an oval shape, a rectangular shape, a square shape, a rhombus shape and a hexagonal shape.

As shown in FIG. 2, the landing pads LP may be arranged in the form of a matrix along the second direction D2 and the first direction D1. The landing pads LP may completely or partially overlap the contact patterns BC in the third direction D3.

The landing pad LP may contain or may comprise a conductive material. The landing pad LP may contain or may comprise at least one of, for example, a doped polysilicon, a conductive metal nitride, a conductive metal silicon nitride, a metal carbonitride, a conductive metal silicide, a conductive metal oxide, a two-dimensional material, metal, and/or a metal alloy.

Pad isolation patterns 235 may be disposed between the landing pads LP. When viewed in a plan view, the pad isolation patterns 235 may at least partially fill a space in which the landing pads LP are arranged in the form of a matrix along the first and second directions D1 and D2.

The pad isolation patterns 235 may be disposed on the contact isolation pattern 231. An upper surface of the pad isolation pattern 235 may be coplanar with an upper surface of the landing pad LP, but embodiments are not limited thereto.

The pad isolation pattern 235 may be disposed on the contact isolation pattern 231 disposed on the peripheral circuit region PCR.

The pad isolation patterns 235 may contain or may comprise an insulating material. The pad isolation patterns 235 may contain or may comprise an oxide-based insulating material, for example, silicon oxide.

The passage pattern OP may be disposed in the mold insulating structure layer 120. The passage pattern OP may pass through the contact isolation pattern 231 and the residual insulating film RP. The passage pattern OP may pass through portions of the contact isolation pattern 231, the residual insulating film RP, the second mold insulating layer 122 and the first mold insulating layer 121. The passage pattern OP may be connected to the first mold insulating layer 121 and the pad isolation pattern 235. The passage pattern OP may be in contact with the first mold insulating layer 121 and the pad isolation pattern 235.

In FIG. 2, the passage pattern OP may be disposed between the bit lines BL adjacent to each other in the first direction D1.

The passage pattern OP may be disposed between the first word line WL1 and the second word line WL2, which are adjacent to each other in the second direction D2. The passage pattern OP may be disposed to be more adjacent or closer to the second portion WLb of the word line than the first portion WLa of the word line. In detail, the passage pattern OP may be disposed between the first portion WLa of the first word line WL1 and the first portion WLa of the second word line WL2, which are adjacent to each other in the second direction D2.

The passage pattern OP may not overlap the channel structure AP_ST in the first direction D1. That is, the passage pattern OP may not be disposed between two channel structures AP_ST adjacent to each other in the first direction D1. As a result, the channel structure AP_ST is less affected in the process of forming the passage pattern OP, whereby a semiconductor memory device having improved electrical characteristics may be provided.

The passage pattern OP is shown in FIG. 2 as having a circular shape or an oval shape, but this is an example and embodiments are not limited thereto. When viewed in a plan view, the passage pattern OP may have various shapes such as, but not limited to, a rectangular shape, a square shape, a rhombus shape and a hexagonal shape.

The passage pattern OP is shown in FIGS. 3 and 4 as having a shape of a cup extended in the third direction D3, but embodiments are not limited thereto. The passage pattern OP may have a shape of a cylinder or an inverted cone.

The passage pattern OP may include an upper surface OP_US and a bottom surface OP_BS, which are opposite to each other in the third direction D3. The bottom surface OP_BS of the passage pattern OP may face the substrate 100 and the bit line BL.

A width of the passage pattern OP in the first direction D1 may be substantially the same as a width in the second direction D2. A width W2 of the passage pattern OP may be narrowed toward the upper surface BL_US of the bit line BL. For example, the width W2 of the passage pattern OP disposed in the contact isolation pattern 231 may be greater than the width W2 of the passage pattern OP disposed in the first mold insulating layer 121.

The passage pattern OP may contain or may comprise an oxide-based insulating material, for example, silicon oxide.

In the semiconductor memory device according to some embodiments, a portion of the passage pattern OP may be disposed in the first mold insulating layer 121. The bottom surface OP_BS of the passage pattern OP may be in contact with the first mold insulating layer 121. The bottom surface OP_BS of the passage pattern OP may not be in contact with the bottom surface 120_BS of the mold insulating structure layer 120. That is, based on the bottom surface BL_BS of the bit line BL, the bottom surface OP_BS of the passage pattern OP may be higher in the D3 direction than the bottom surface 120_BS of the mold insulating structure layer 120. In other words, a height from the bottom surface BL_BS of the bit line BL to the bottom surface OP_BS of the passage pattern OP is greater than the height from the bottom surface BL_BS of the bit line BL to the bottom surface 120_BS of the mold insulating structure layer 120.

In the semiconductor memory device according to some embodiments, the upper surface OP_US of the passage pattern OP may be in contact with the pad isolation pattern 235. The upper surface OP_US of the passage pattern OP may be in contact with the bottom surface of the pad isolation pattern 235. That is, the passage pattern OP may not be disposed in the pad isolation pattern 235.

The pad isolation pattern 235 may contain an oxide-based insulating material, and the pad isolation pattern 235 may be connected to a cell interlayer insulating layer 380 and a cell upper insulating layer 480, which will be described below. The passage pattern OP may be in contact with the pad isolation pattern 235 and thus used as a passage through which oxygen of the pad isolation pattern 235, the cell interlayer insulating layer 380, and the cell upper insulating layer 480 is supplied. Oxygen passing through the passage pattern OP may move to the mold insulating structure layer 120. Oxygen moving to the mold insulating structure layer 120 through the passage pattern OP may be supplied to the channel structure AP_ST. As a result, reliability of the channel structure AP_ST may be improved.

The cutting pattern TP may be disposed by passing through the residual cutting film RP, the mold insulating structure layer 120, the lower etching stop film 147, the cell lower insulation layer 131, and the gate isolation pattern GSS.

The cutting pattern TP may be disposed to be adjacent to a boundary between the cell array region CAR and the peripheral circuit region PCR in the second direction D2. The cutting pattern TP may be extended in the second direction D2.

The cutting pattern TP may be in contact with the residual insulating film RP, the mold insulating structure layer 120, the lower etching stop film 147, the cell lower insulating layer 131 and the gate isolation pattern GSS. The cutting pattern TP may be in contact with an upper surface of the fifth peripheral upper insulating layer 265 and a bottom surface of the cell lower insulating layer 131.

In FIG. 2, the cutting pattern TP may be in contact with the first word line WL1 and the second word line WL2. The cutting pattern TP may be in contact with an end of each of the first word line WL1 and the second word line WL2. The end of each of the first word line WL1 and the second word line WL2 means end portions at both ends of each of the first word line WL1 and the second word line WL2 in the first direction D1. The cutting pattern TP may cross the first word line WL1 and the second word line WL2.

A width W1 of the cutting pattern TP in the first direction D1 may be narrowed toward the upper surface BL_US of the bit line BL in the third direction D3. That is, the width W1 of the cutting pattern TP in the first direction D1 in the residual insulating film RP may be greater than the width W1 of the cutting pattern TP in the first direction D1 in the cell lower insulating layer 131.

The cutting pattern TP may contain an oxide-based insulating material, for example, silicon oxide.

In the semiconductor memory device according to some embodiments, the upper surface OP_US of the passage pattern OP may be higher than an upper surface TP_US of the cutting pattern TP based on the bottom surface BL_BS of the bit line BL. The upper surface TP_US of the cutting pattern TP may be in contact with the contact isolation pattern 231. The upper surface TP_US of the cutting pattern TP may be in contact with a bottom surface of the contact isolation pattern 231. That is, the cutting pattern TP may not be disposed inside the contact isolation pattern 231.

The data storage patterns DSP may be disposed on the landing pads LP, respectively. The data storage patterns DSP may be in contact with all or some of the upper surfaces of the landing pads LP. The data storage patterns DSP may be connected to the landing pads LP. The data storage patterns DSP may be connected to the first channel pattern AP1 and the second channel pattern AP2, respectively.

An upper etching stop film 247 may be disposed on the landing pads LP and the pad isolation pattern 235. The upper etching stop film 247 may be extended to the peripheral circuit region PCR. The upper etching stop film 247 may be made of or may comprise an insulating material.

As shown in FIG. 2, the data storage patterns DSP may be arranged in the form of a matrix along the second direction D2 and the first direction D1. The data storage patterns DSP may completely or partially overlap the landing pads LP in the third direction D3.

For example, the data storage patterns DSP may be capacitors. Each of the first channel pattern AP1 and the second channel pattern AP2 may be connected to a capacitor.

The data storage patterns DSP may include a capacitor dielectric film 253 interposed between storage electrodes 251 and a plate electrode 255. In this case, the storage electrode 251 may be in contact with the landing pad LP. When viewed in a plan view, the storage electrode 251 may have various shapes, such as, but not limited to, a circular shape, an oval shape, a rectangular shape, a square shape, a rhombus shape and a hexagonal shape. The storage electrodes 251 may completely or partially overlap the landing pads LP. The storage electrodes 251 may be in contact with all or some of the upper surfaces of the landing pads LP. The storage electrodes 251 may pass through the upper etching stop film 247.

The plate electrode 255 may include a lower plate electrode 255a and an upper plate electrode 255b. Unlike the shown example, the plate electrode 255 may be a single layer. Each of the storage electrode 251 and the plate electrode 255 may contain or may comprise at least one of, for example, a conductive semiconductor material, a conductive metal nitride, a conductive metal silicon nitride, a metal carbonitride, a conductive metal silicide, a conductive metal oxide, and/or metal. The capacitor dielectric film 253 may contain or may comprise at least one of a ferroelectric material, an antiferroelectric material, and/or a paraelectric material. For example, the capacitor dielectric film 253 may contain or may comprise one of a ferroelectric material, an antiferroelectric material, a paraelectric material, combination of a ferroelectric material and an antiferroelectric material, combination of a ferroelectric material and a paraelectric material, combination of a paraelectric material and an antiferroelectric material, and combination of a ferroelectric material, an antiferroelectric material and a paraelectric material.

In other embodiments, the data storage patterns DSP may be variable resistance patterns that may be switched to two resistance states by an electrical pulse applied to a memory element. For example, the data storage patterns DSP may contain or may comprise a phase-change material in which a crystal state is changed in accordance with the amount of current, perovskite compounds, a transition metal oxide, magnetic materials, ferromagnetic materials, and/or antiferromagnetic materials.

The cell upper insulating layer 480 may be disposed on the plate electrode 255. The cell upper insulating layer 480 may be disposed on the cell array region CAR and the peripheral circuit region PCR. The cell upper insulating layer 480 may contain or may comprise an oxide-based insulating material, for example, silicon oxide.

An upper wiring structure 450 may be disposed on the cell array region CAR and the peripheral circuit region PCR. The upper wiring structure 450 may be disposed in the cell upper insulation layer 480. The upper wiring structure 450 may be disposed on the data storage pattern DSP. The upper wiring structure 450 may be electrically connected to the data storage pattern DSP. That is, the upper wiring structure 450 may be electrically connected to the capacitor.

The contact via CV may be disposed on the peripheral circuit region PCR outside the cell array region CAR. The contact via CV may be disposed to be spaced apart from the bit line BL in the second direction D2. The contact via CV may be disposed to pass through the upper etching stop film 247, the cell interlayer insulating layer 380, and the lower etching stop film 147. The cell interlayer insulating layer 380 may contain an oxide-based insulating material, for example, silicon oxide.

The contact via CV may be electrically connected to the upper wiring structure 450 and the second peripheral wiring line 243. The second peripheral wiring line 243 may be directly connected to the contact via CV. A width of the contact via CV may become narrower with increasing distance from the upper wiring structure 450 in the third direction D3. That is, the width of the contact via CV may become narrower as the contact via CV becomes closer to the second peripheral wiring line 243 from the upper wiring structure 450.

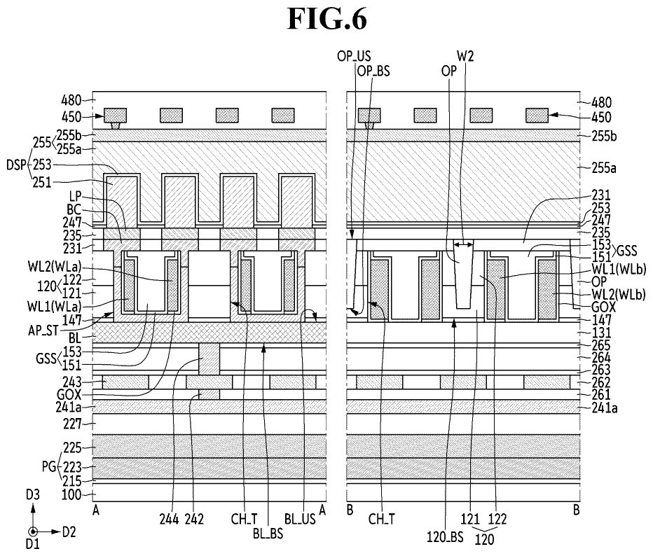

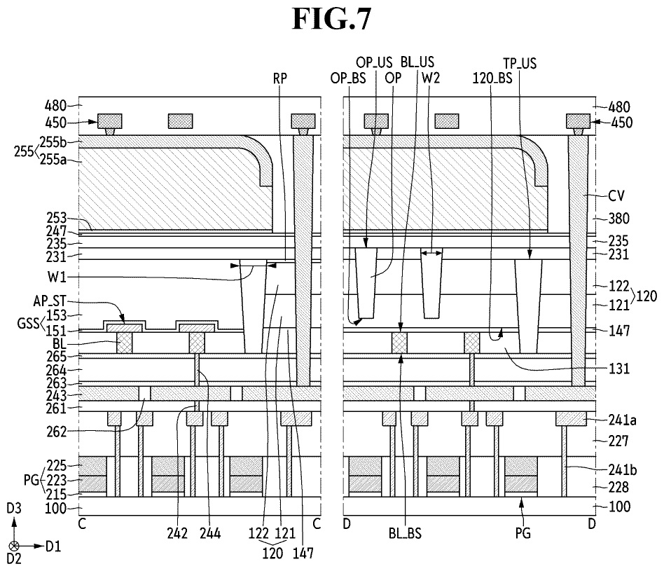

FIGS. 6 and 7 are views illustrating a semiconductor memory device according to some embodiments. For convenience of description, the description will be based on differences from those described with reference to FIGS. 1 to 5. For reference, FIG. 6 is a cross-sectional view taken along lines A-A and B-B of FIG. 2, and FIG. 7 is a cross-sectional view taken along lines C-C and D-D of FIG. 2.

Referring to FIGS. 6 and 7, the residual insulating film RP may not exist in the semiconductor memory device according to some embodiments.

The passage pattern OP may not pass through the residual insulating film RP. The cutting pattern TP may not pass through the residual insulating film RP. The contact isolation pattern 231 may be in contact with the second mold insulating layer 122.

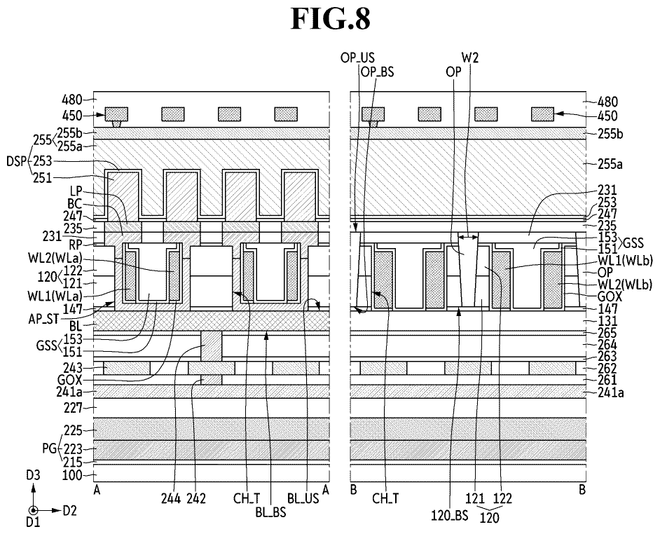

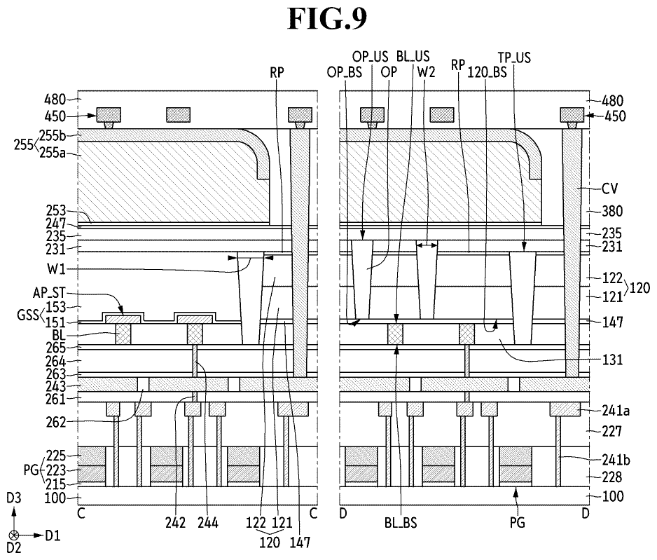

FIGS. 8 and 9 are views illustrating a semiconductor memory device according to some embodiments. For convenience of description, the description will be based on differences from those described with reference to FIGS. 1 to 7. For reference, FIG. 8 is a cross-sectional view taken along lines A-A and B-B of FIG. 2, and FIG. 9 is a cross-sectional view taken along lines C-C and D-D of FIG. 2.

Referring to FIGS. 8 and 9, in the semiconductor memory device according to some embodiments, the passage pattern OP may be in contact with the lower etching stop film 147 by passing through the first mold insulating layer 121.

The bottom surface OP_BS of the passage pattern OP may be in contact with the lower etching stop film 147. In other words, based on the bottom surface BL_BS of the bit line BL, a height to the bottom surface OP_BS of the passage pattern OP and a height to the bottom surface of the lower etching stop film 147, that is, the bottom surface 120_BS of the mold insulating structure layer 120 may be the same as each other.

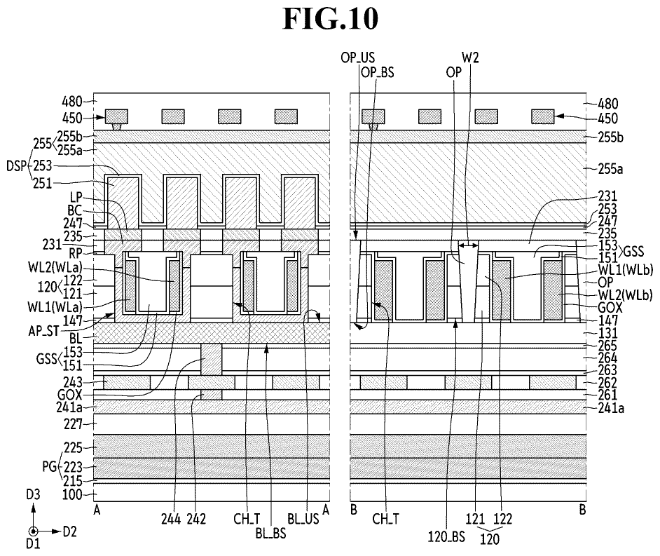

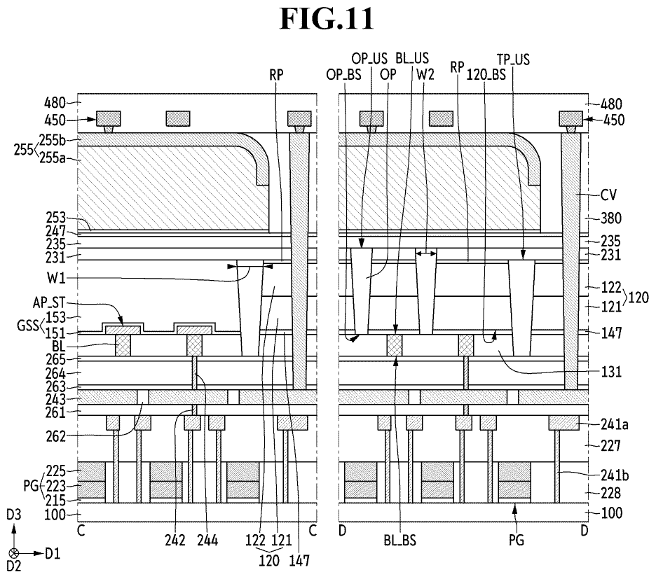

FIGS. 10 and 11 are views illustrating a semiconductor memory device according to some embodiments. For convenience of description, the description will be based on differences from those described with reference to FIGS. 1 to 9. For reference, FIG. 10 is a cross-sectional view taken along lines A-A and B-B of FIG. 2, and FIG. 11 is a cross-sectional view taken along lines C-C and D-D of FIG. 2.

Referring to FIGS. 10 and 11, in the semiconductor memory device according to some embodiments, the passage pattern OP may be in contact with the cell lower insulating layer 131 by passing through the lower etching stop film 147.

The bottom surface OP_BS of the passage pattern OP may be in contact with the cell lower insulating layer 131. In other words, based on the bottom surface BL_BS of the bit line BL, the bottom surface 120_BS of the mold insulating structure layer 120 may be higher than the bottom surface OP_BS of the passage pattern OP.

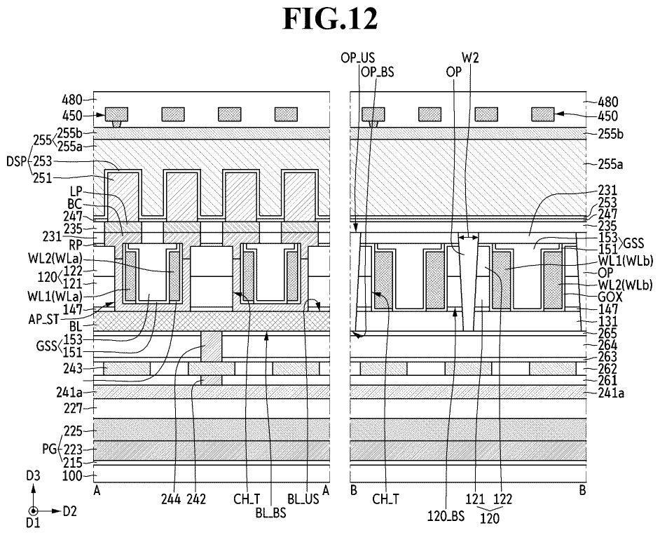

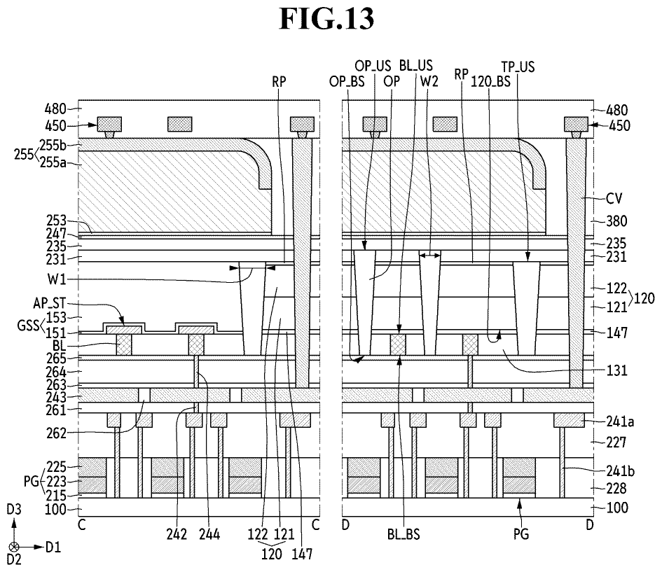

FIGS. 12 and 13 are views illustrating a semiconductor memory device according to some embodiments. For convenience of description, the description will be based on differences from those described with reference to FIGS. 1 to 11. For reference, FIG. 12 is a cross-sectional view taken along lines A-A and B-B of FIG. 2, and FIG. 13 is a cross-sectional view taken along lines C-C and D-D of FIG. 2.

Referring to FIGS. 12 and 13, in the semiconductor memory device according to some embodiments, a portion of the passage pattern OP may be disposed inside the cell lower insulating layer 131 by passing through the cell lower insulating layer 131.

The bottom surface OP_BS of the passage pattern OP and the bottom surface of the cell lower insulating layer 131 may be coplanar with each other. The bottom surface OP_BS of the passage pattern OP, the bottom surface of the cutting pattern TP, and the bottom surface BL_BS of the bit line BL may be coplanar with one another.

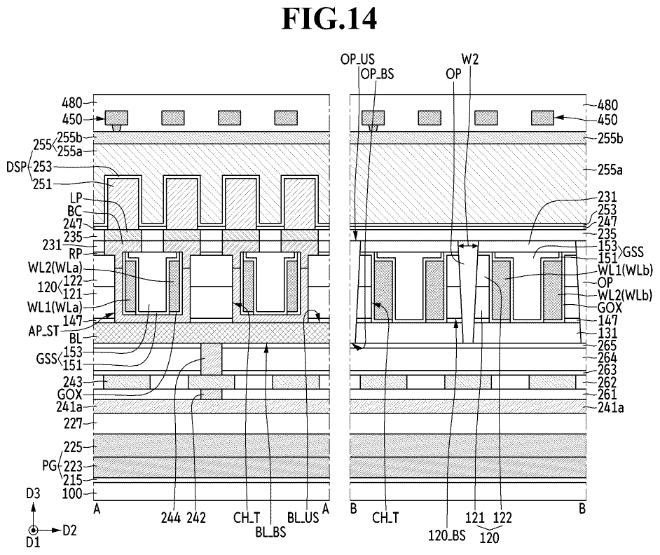

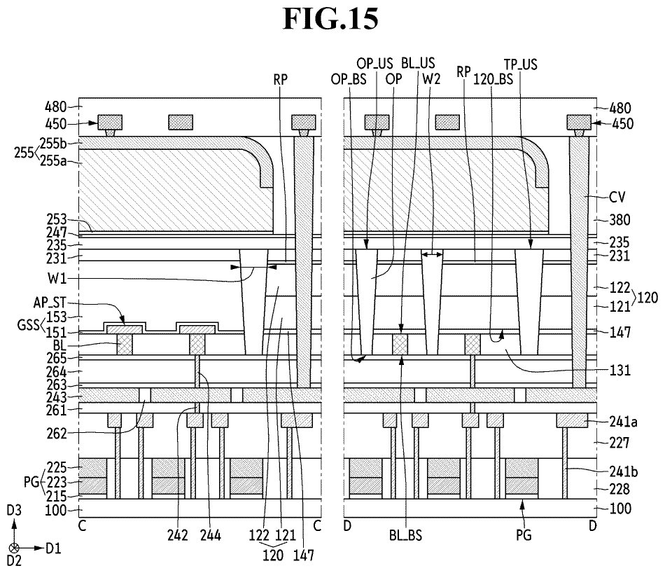

FIGS. 14 and 15 are views illustrating a semiconductor memory device according to some embodiments. For convenience of description, the description will be based on differences from those described with reference to FIGS. 1 to 13. For reference, FIG. 14 is a cross-sectional view taken along lines A-A and B-B of FIG. 2, and FIG. 15 is a cross-sectional view taken along lines C-C and D-D of FIG. 2.

Referring to FIGS. 14 and 15, in the semiconductor memory device according to some embodiments, the upper surface OP_US of the passage pattern OP and the upper surface TP_US of the cutting pattern TP may be coplanar with each other.

The upper surface OP_US of the passage pattern OP may be coplanar with an upper surface of the contact isolation pattern 231. The upper surface TP_US of the cutting pattern TP may be coplanar with the upper surface of the contact isolation pattern 231. In other words, based on the bottom surface BL_BS of the bit line BL, the upper surface OP_US of the passage pattern OP and the upper surface TP_US of the cutting pattern TP may have substantially the same height.

The passage pattern OP may be disposed by passing through the cell lower insulating layer 131. That is, the bottom surface OP_BS of the passage pattern OP may be coplanar with the bottom surface of the cell lower insulating layer 231.

A portion of the cutting pattern TP may be disposed inside the contact isolation pattern 231 by passing through the contact isolation pattern 231.

The cutting pattern TP and the passage pattern OP may contain or may comprise the same material. The cutting pattern TP and the passage pattern OP may contain or may comprise an oxide-based insulating material, for example, silicon oxide. This may be because, as will be described below, the cutting pattern TP and the passage pattern OP are formed at the same level in the process, that is, at the same operation in the process.

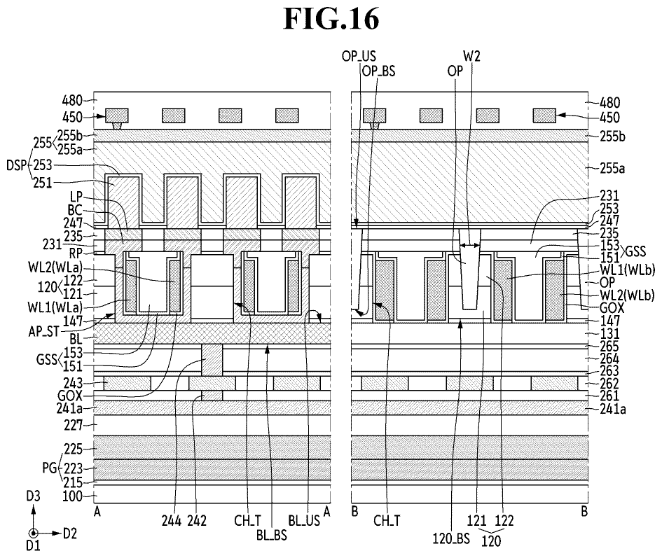

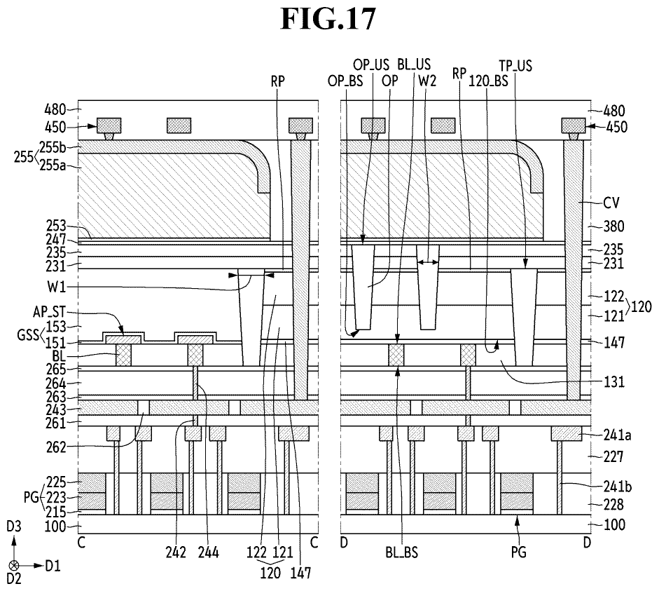

FIGS. 16 and 17 are views illustrating a semiconductor memory device according to some embodiments. For convenience of description, the description will be based on differences from those described with reference to FIGS. 1 to 15. For reference, FIG. 15 is a cross-sectional view taken along lines A-A and B-B of FIG. 2, and FIG. 16 is a cross-sectional view taken along lines C-C and D-D of FIG. 2.

Referring to FIGS. 16 and 17, in the semiconductor memory device according to some embodiments, a portion of the passage pattern OP may be disposed inside the pad isolation pattern 235 by passing through the pad isolation pattern 235.

The upper surface OP_US of the passage pattern OP may be coplanar with the upper surface of the pad isolation pattern 235. That is, the upper surface of the pad isolation pattern 235 may be in contact with the bottom surface of the upper etching stop film 247. The passage pattern OP may not pass through the upper etching stop film 247.

The passage pattern OP may pass through the pad isolation pattern 235, the contact isolation pattern 231, the residual insulating film RP and the second insulating structure layer 122. The passage pattern OP may pass through a portion of the first insulating structure layer 121.

In the semiconductor memory device according to some embodiments, the passage pattern OP may be formed after the landing pad LP and the pad isolation pattern 235 are formed.

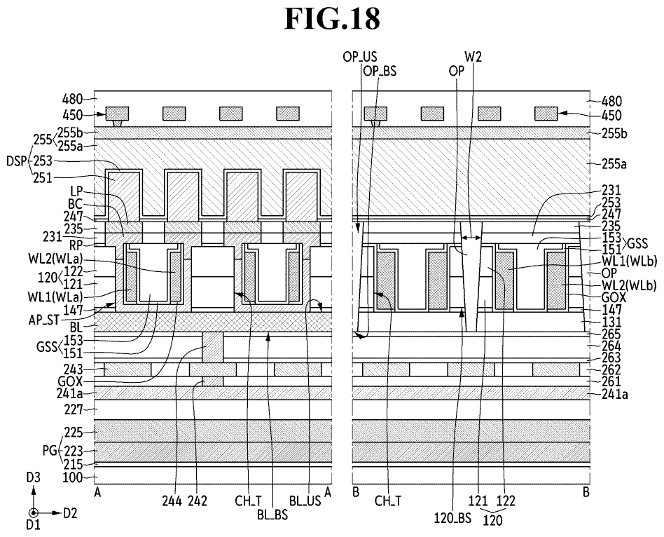

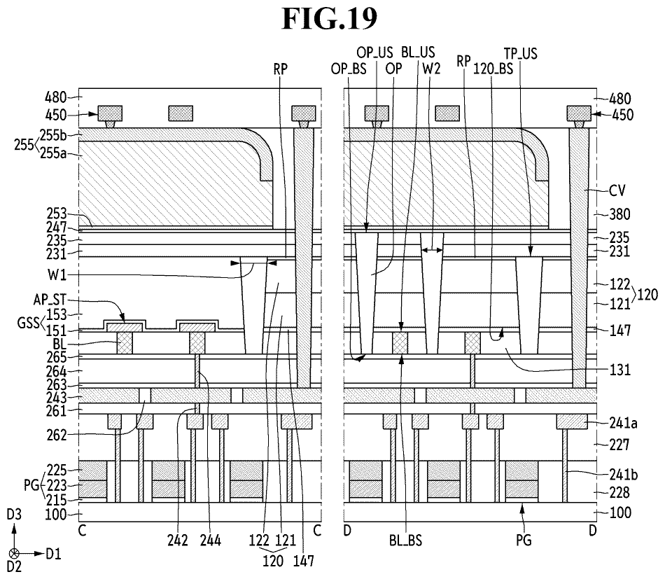

FIGS. 18 and 19 are views illustrating a semiconductor memory device according to some embodiments. For convenience of description, the description will be based on differences from those described with reference to FIGS. 1 to 17. For reference, FIG. 18 is a cross-sectional view taken along lines A-A and B-B of FIG. 2, and FIG. 19 is a cross-sectional view taken along lines C-C and D-D of FIG. 2.

Referring to FIGS. 18 and 19, in the semiconductor memory device according to some embodiments, a portion of the passage pattern OP may be disposed inside the cell lower insulating layer 131 by passing through the cell lower insulating layer 131.

The bottom surface OP_BS of the passage pattern OP and the bottom surface of the cell lower insulating layer 131 may be coplanar with each other. The bottom surface OP_BS of the passage pattern OP, the bottom surface of the cutting pattern TP and the bottom surface BL_BS of the bit line BL may be coplanar with one another.

The upper surface OP_US of the passage pattern OP may be coplanar with the upper surface of the pad isolation pattern 235.

The passage pattern OP may be disposed by passing through the pad isolation pattern 235, the contact isolation pattern 231, the mold insulating structure layer 120, the lower etching stop film 147 and the cell lower insulating layer 131.

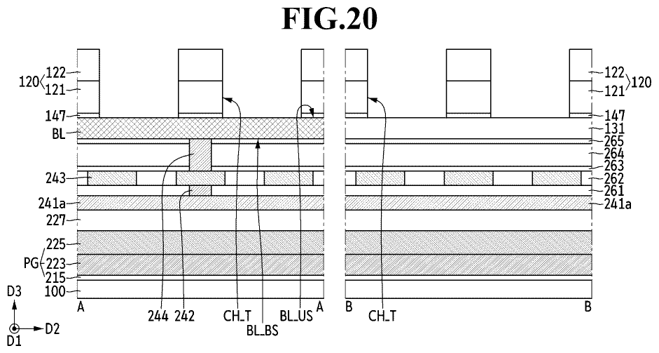

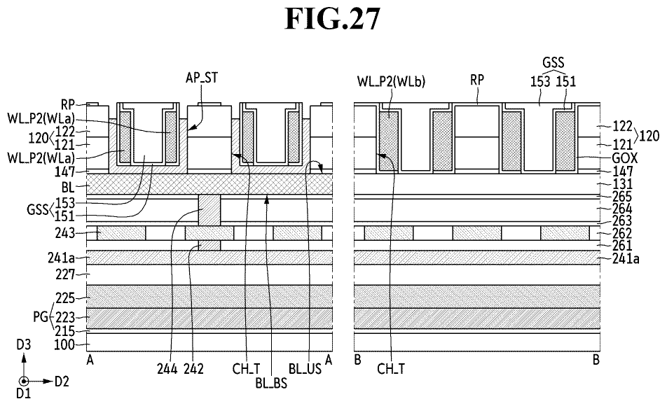

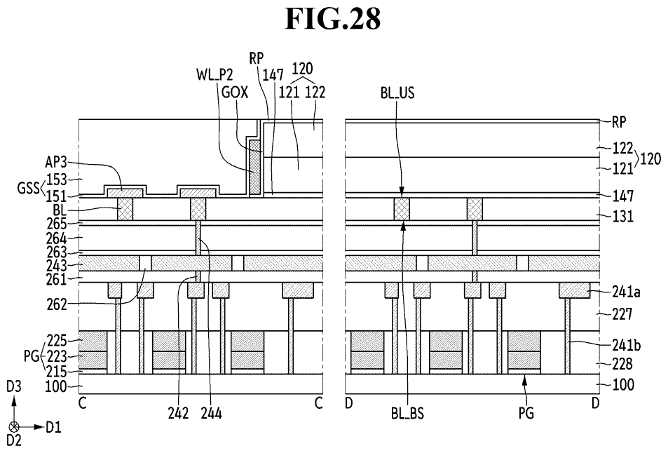

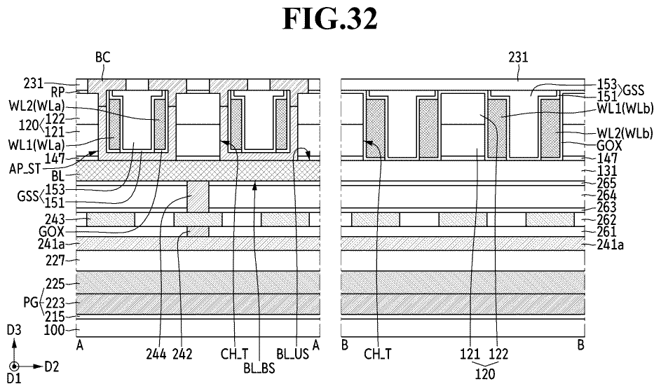

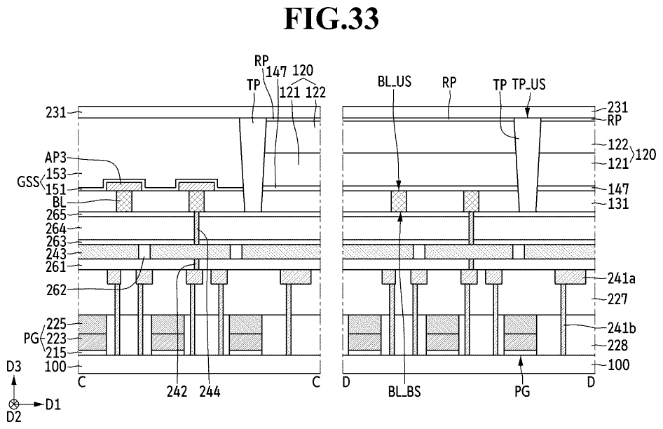

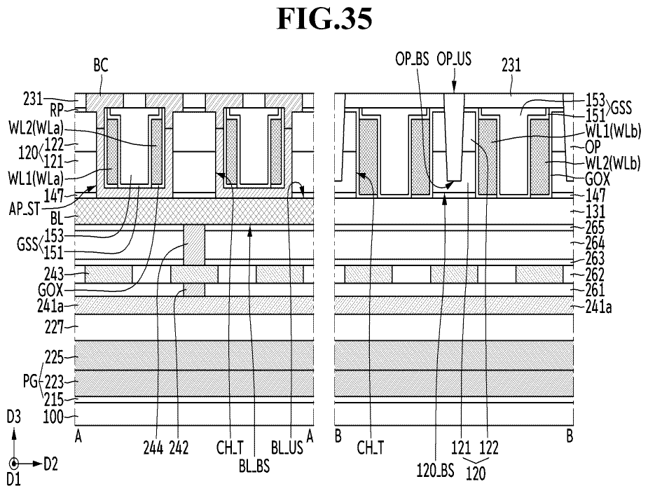

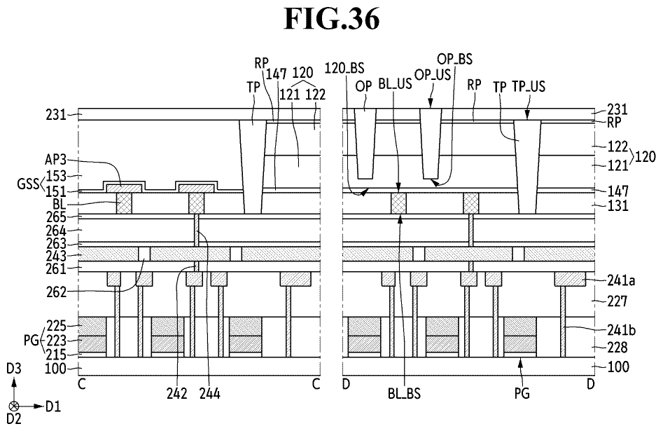

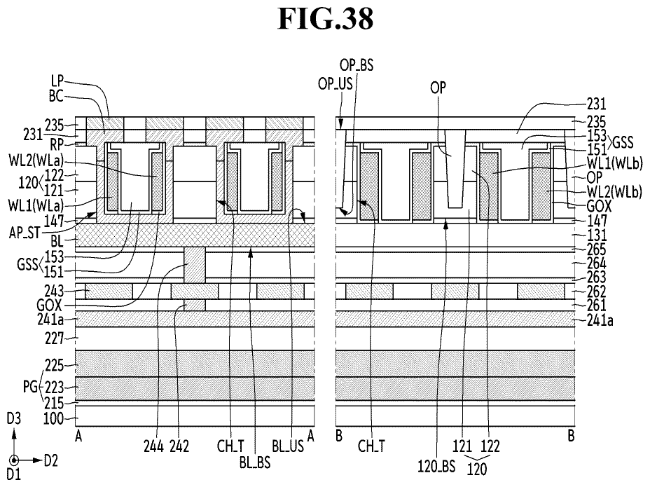

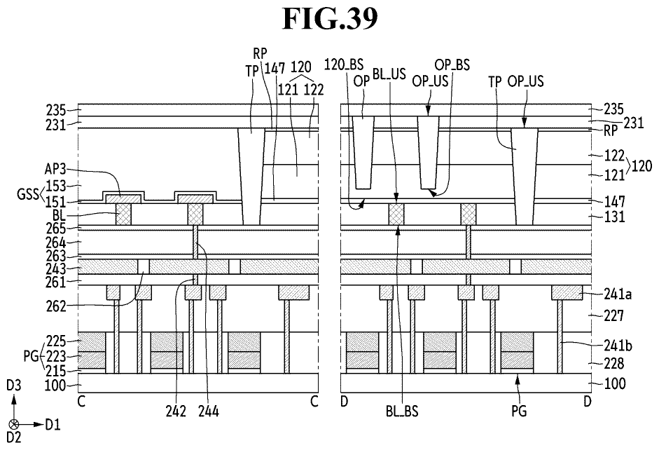

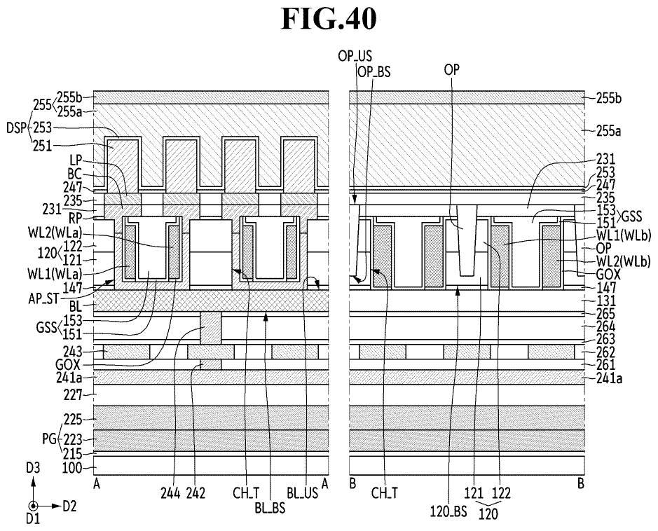

FIGS. 20 to 40 are views illustrating intermediate operations of a method for fabricating a semiconductor memory device according to some embodiments.

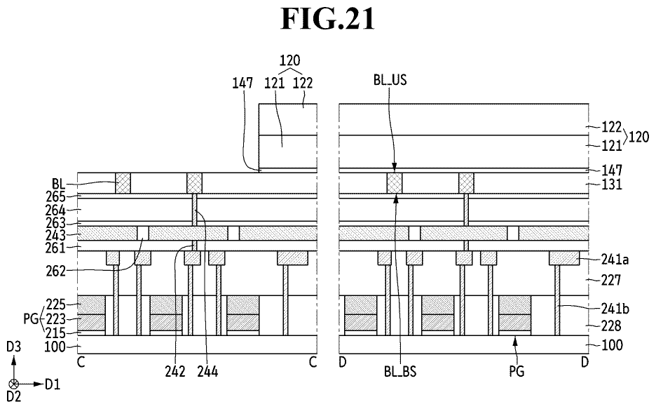

Referring to FIGS. 20 and 21, the peripheral gate structure PG may be formed on the substrate 100.

The first peripheral wiring line 241a and the peripheral contact plug 241b may be formed on the substrate 100.

The peripheral upper insulating layers 261, 262, 263, 264 and 265 may be sequentially formed on the first peripheral wiring line 241a and the peripheral contact plug 241b. The second peripheral wiring line 243, the peripheral via plug 242 and the cell connection plug 244 may be formed in the peripheral upper insulating layers 261, 262, 263, 264 and 265.

Subsequently, the bit lines BL may be formed on the fifth peripheral upper insulating layer 265. The bit line BL may be extended lengthwise in the second direction D2 on the substrate 100. The cell lower insulating layer 131 may be formed on the fifth peripheral upper insulating layer 265. The cell lower insulating layer 131 may at least partially expose the upper surface BL_US of the bit line BL.

Subsequently, the lower etching stop film 147 may be formed on the bit line BL and the cell lower insulating layer 131.

Subsequently, the mold insulating structure layer 120 may be formed on the bit line BL and the cell lower insulating layer 131. The mold insulating structure layer 120 may be formed on the lower etching stop film 147. In detail, the mold insulating structure layer 120 may be formed on the lower etching stop film 147 in the order of the first mold insulating layer 121 and the second mold insulating layer 122.

The first mold insulating layer 121 may be formed of a silicon oxide-based insulating material on the lower etching stop film 147. For example, the first mold insulating layer 121 may be formed of silicon oxide. The second mold insulating layer 122 may be formed of a silicon nitride-based insulating material on the first mold insulating layer 121. For example, the second mold insulating layer 122 may be formed of silicon nitride.

The mold insulating structure layer 120 may include a plurality of channel trenches CH_T extended in the first direction D1. The channel trench CH_T may cross the bit line BL. The channel trench CH_T may expose the bit line BL.

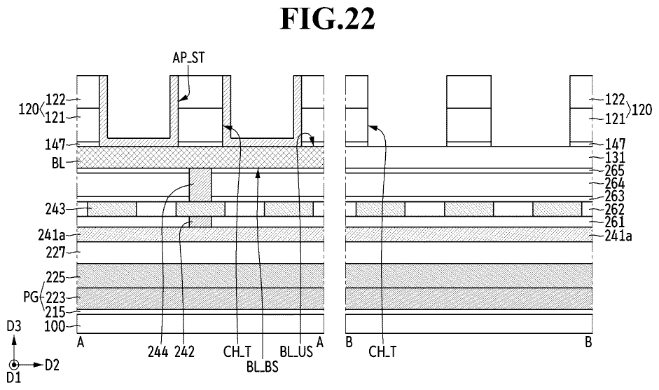

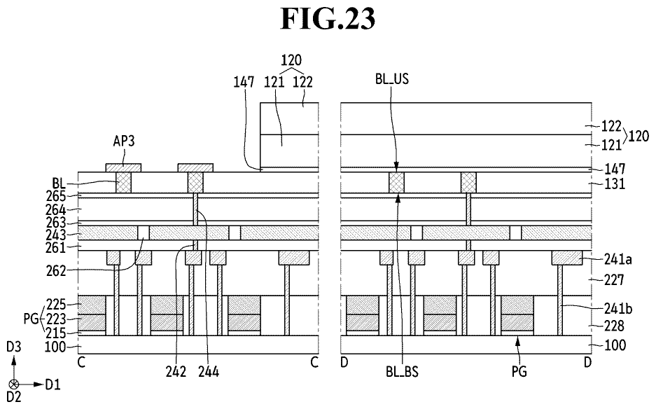

Referring to FIGS. 22 and 23, a pre-channel structure may be formed in the channel trench CH_T.

The pre-channel structure may be formed on the mold insulating structure layer 120, the bit line BL and the cell lower insulating layer 131. The pre-channel structure may be formed along the sidewalls of the mold insulating structure layer 120 and the sidewalls of the lower etching stop film 147.

Subsequently, the pre-channel structure may be removed by an etching process so that the channel structure AP_ST may be formed. The channel structure AP_ST may be formed to be extended along the sidewalls and the bottom surface of the channel trench CH_T.

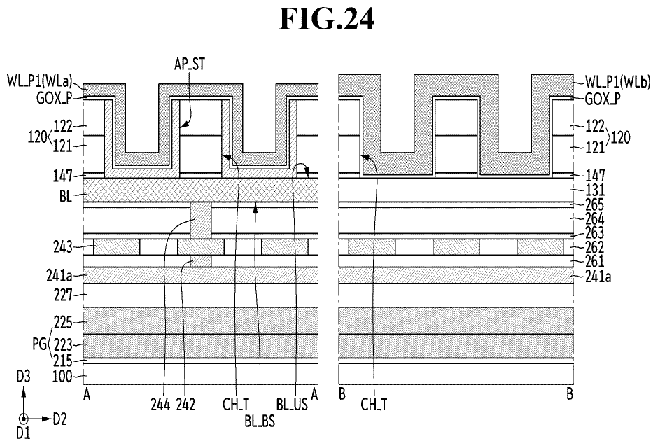

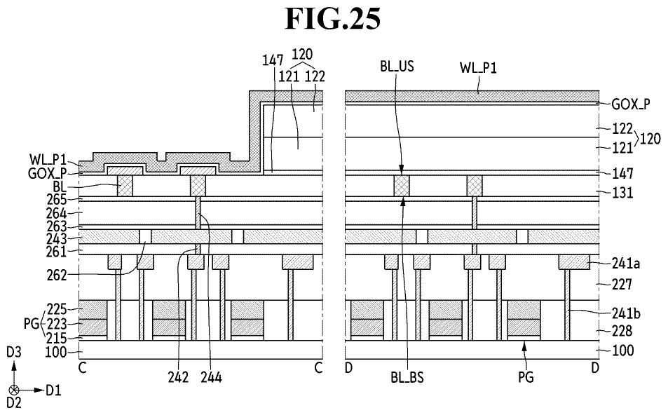

Referring to FIGS. 24 and 25, a pre-gate insulating film GOX_P may be formed on the mold insulating layer 120, the channel structure AP_ST and the cell lower insulating layer 131.

The pre-gate insulating film GOX_P may be formed along the upper surface and sidewalls of the mold insulating structure layer 120, the upper surface and sidewalls of the channel structure AP_ST, the sidewalls of the lower etching stop film 147 and the upper surface of the cell lower insulating layer 131. The pre-gate insulating film GOX_P may be formed by using at least one of physical vapor deposition (PVD), thermal chemical vapor deposition (CVD), low pressure chemical vapor deposition (LP-CVD), plasma-enhanced chemical vapor deposition (PE-CVD) and/or atomic layer deposition (ALD), but embodiments are not limited thereto.

Subsequently, a first pre-word line WL_P1 may be formed to be extended along an upper surface and sidewalls of the pre-gate insulating film GOX_P.

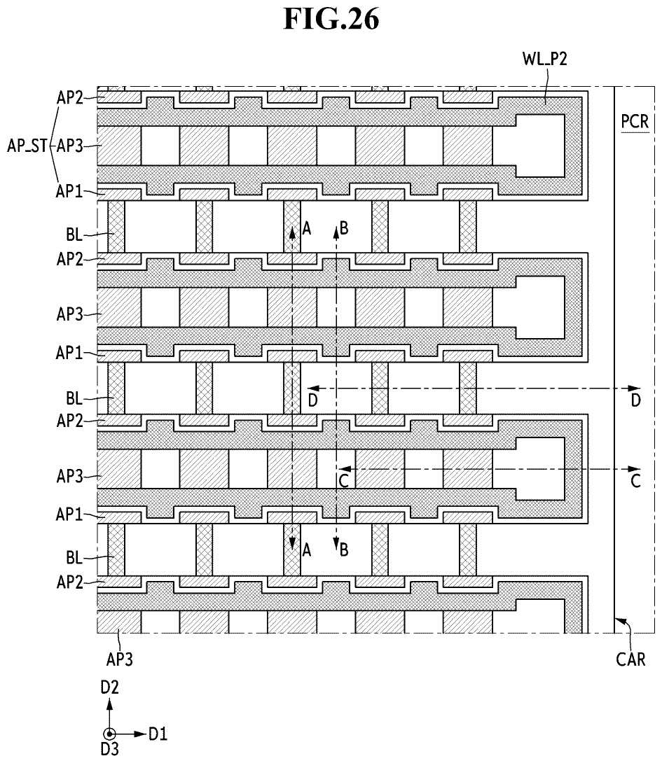

Referring to FIGS. 26 to 28, a plurality of second pre-word lines WL_P2 extended along the first direction D1 may be formed.

Each of the plurality of second pre-word lines WL_P2 may be formed to be spaced apart from each other along the second direction D2. The plurality of second pre-word lines WL_P2 may be formed by removing a portion of the first pre-word line (see WL_P1 of FIG. 25) through an etching process.

Each of the second pre-word lines WL_P2 may be formed to have a first portion and a second portion, which are extended along the first direction D1, and a third portion extended in the second direction D2, electrically connecting the first portion with the second portion.

In detail, the first portion and the second portion may be formed through an anisotropic etching process for the first pre-word line WL_P1. In this case, the first pre-word line WL_P1 formed on the upper surface of the mold insulating structure layer 120 may be removed. Also, a portion of the first pre-word line WL_P1 formed along the sidewalls of the pre-gate insulating film (see GOX_P in FIG. 25) may be removed.

A portion of the pre-gate insulating film GOX_P may be etched while the second pre-word line WL_P2 is being formed. As a result, the pre-gate insulating film GOX_P between the first portion of the second pre-word line WL_P2 and the channel structure AP_ST may be separated from the pre-gate insulating film GOX_P between the second portion of the second pre-word line WL_P2 and the channel structure AP_ST.

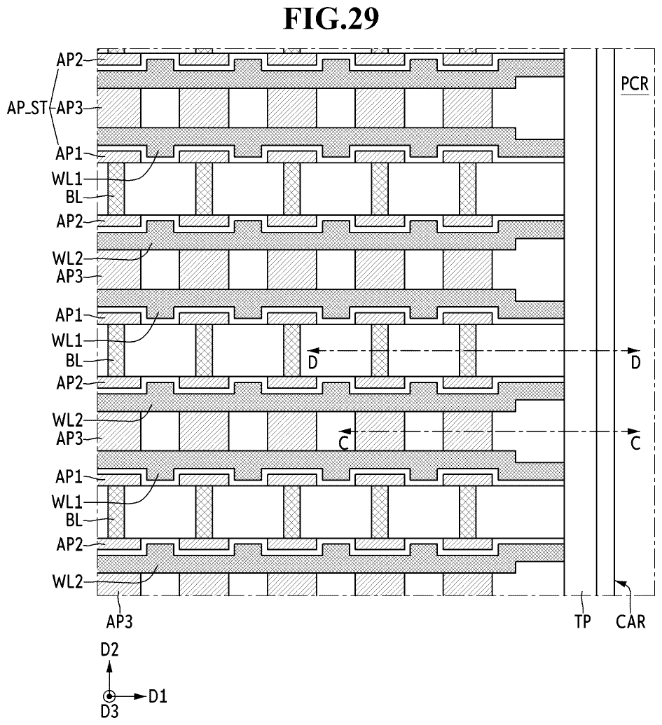

The first portion and the second portion of the second pre-word line WL_P2 may later form a first word line (see WL1 of FIG. 29) and a second word line (see WL2 of FIG. 29), respectively. The third portion may be formed to be adjacent to the boundary between the cell array region CAR and the peripheral circuit region PCR in the second direction D2.

Subsequently, the gate isolation pattern GSS may be formed on the second pre-word line WL_P2. In detail, the gate isolation liner 151 may be formed along a profile of the first portion and the second portion of the second pre-word line WL_P2. The gate isolation filling layer 153 may be formed on the gate isolation liner 151.

Subsequently, a portion of the pre-gate insulating film GOX_P on the upper surface of the channel structure AP_ST and the upper surface of the second mold insulating layer 122 may be removed by an etching process. As a result, a portion of the pre-gate insulating film GOX_P, which is not removed, may form the residual insulating film RP on the second mold insulating layer 122, and the other portion of the pre-gate insulating film GOX_P, which is not removed, may form the gate insulating film GOX. Also, the upper surface of the channel structure AP_ST may be exposed. Unlike the shown example, the pre-gate insulating film GOX_P on the upper surface of the second mold insulating layer 122 may not be removed.

Afterwards, the channel structure AP_ST is partially removed through anisotropic etching, so that the upper surface of the second mold insulating layer 122 may be formed to be higher in the D2 direction than the upper surface of the channel structure AP_ST based on the upper surface BL_US of the bit line BL.

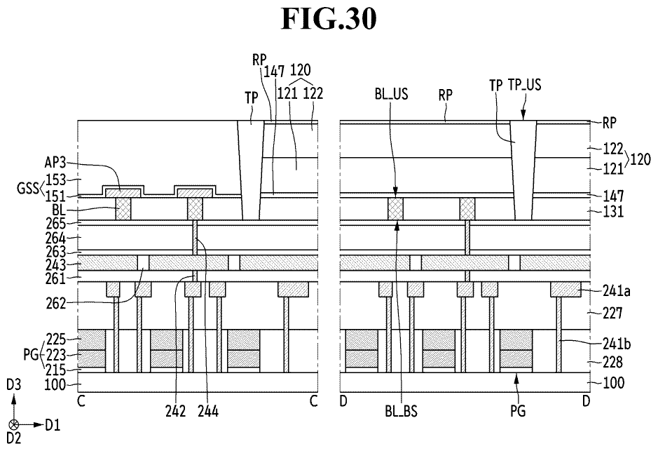

Referring to FIGS. 29 and 30, a pre-cutting pattern passing through the residual insulating film RP, the mold insulating structure layer 120, the gate isolation pattern GSS, the lower etching stop film 147, the gate insulating film GOX, the second pre-word line (see WL_P2 of FIG. 26), and the cell lower insulating layer 131 may be formed through an etching process.

In detail, the pre-cutting pattern may be formed to be adjacent to the boundary between the cell array region CAR and the peripheral circuit region PCR in the second direction D2. The pre-cutting pattern may be extended along the second direction D2. The pre-cutting pattern may be formed by removing the third portion of the second pre-word line WL_P2. As a result, the second pre-word line WL_P2 may form the first word line WL1 and the second word line WL2.

Subsequently, the pre-cutting pattern may be at least partially filled with an oxide-based material so that the cutting pattern TP may be formed. The oxide-based material may contain, for example, silicon oxide.

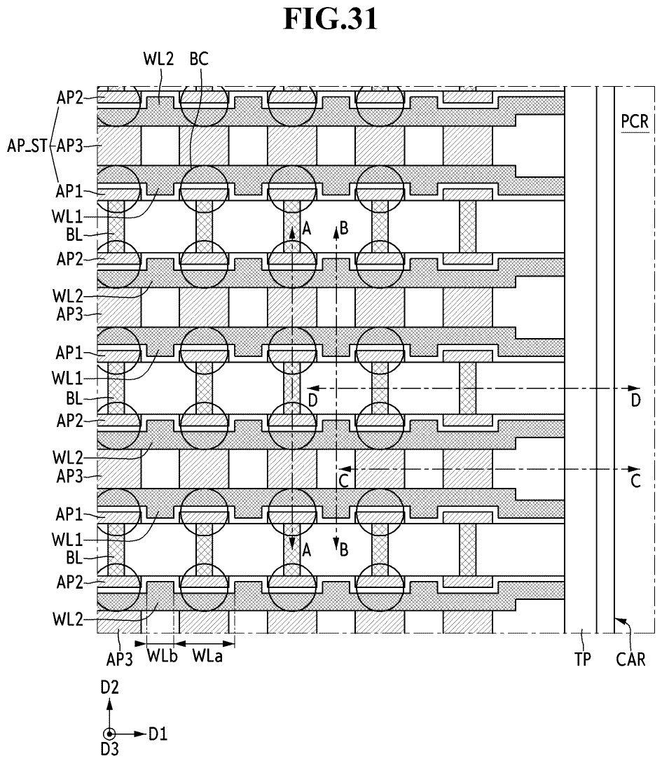

Referring to FIGS. 31 to 33, the contact isolation pattern 231 for at least partially exposing the upper surface of the channel structure AP_ST may be formed on the residual insulating film RP, the gate isolation pattern GSS and the cutting pattern TP.

Subsequently, the contact pattern BC may be formed between the contact isolation patterns 231. The contact pattern BC may be formed on the channel structure AP_ST. The contact pattern BC may be connected to the channel structure AP_ST.

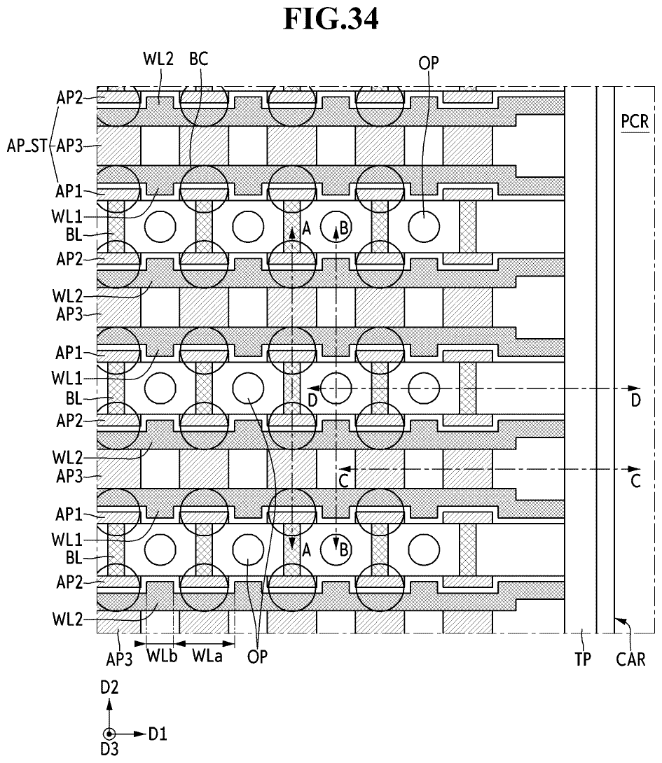

Referring to FIGS. 34 to 36, the passage pattern OP may be formed by passing through a portion of the contact isolation pattern 231, the residual insulating film RP, the lower etching stop film 147 and the mold insulating structure layer 120.

In detail, the passage pattern OP may be formed between the bit lines BL adjacent to each other in the first direction D1. The passage pattern OP may be formed between the second portion WL_b of the first word line WL1 and the second portion WL_b of the second word line WL2, which are adjacent to each other in the second direction D2. The passage pattern OP may contain or may comprise an oxide-based insulating material, for example, silicon oxide.

Also, in detail, in the semiconductor memory device according to some embodiments, the upper surface OP_US of the passage pattern OP may be formed to be higher in the D3 direction than the upper surface TP_US of the cutting pattern TP based on the bottom surface BL_BS of the bit line BL. The bottom surface OP_BS of the passage pattern OP may be formed to be higher in the D3 direction than the bottom surface 120_BS of the mold insulating structure layer 120 based on the bottom surface BL_BS of the bit line BL.

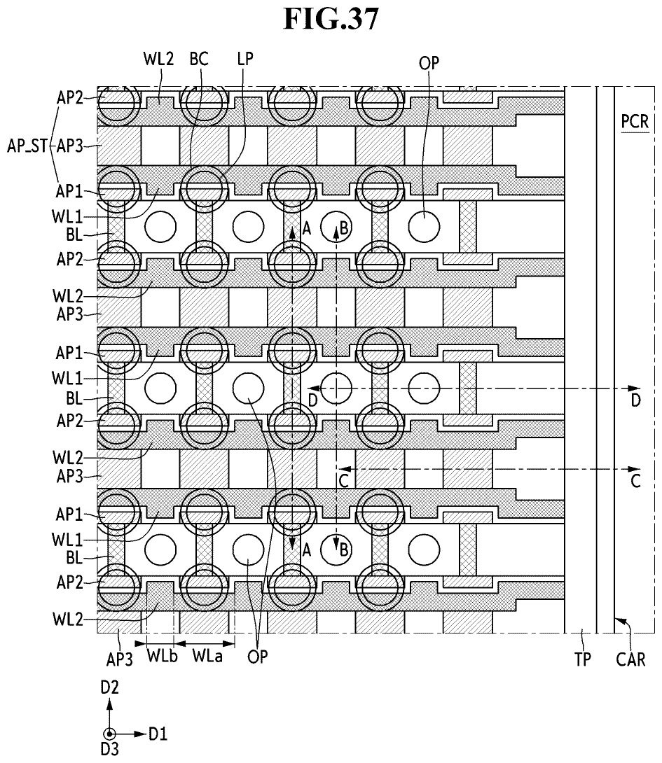

Referring to FIGS. 37 to 40, the pad isolation pattern 235 for at least partially exposing an upper surface of the contact pattern BC may be formed on the contact isolation pattern 231 and the passage pattern OP.

In detail, the pad isolation pattern 235 may be formed to be in contact with the upper surface of the contact isolation pattern 231 and the upper surface OP_US of the passage pattern OP.

Subsequently, the landing pad LP may be formed between the pad isolation patterns 235. The landing pad LP may be formed on the contact pattern BC. The landing pad LP may be electrically connected to the contact pattern BC.

Subsequently, the data storage patterns DSP may be formed on the landing pad LP and the pad isolation pattern 235.

Subsequently, referring to FIGS. 2 to 4, the cell upper insulating layer 480 and the upper wiring structure 450 may be formed on the data storage pattern DSP. Subsequently, the contact via CV for electrically connecting the upper wiring structure 450 with the second peripheral wiring line 243 may be formed.

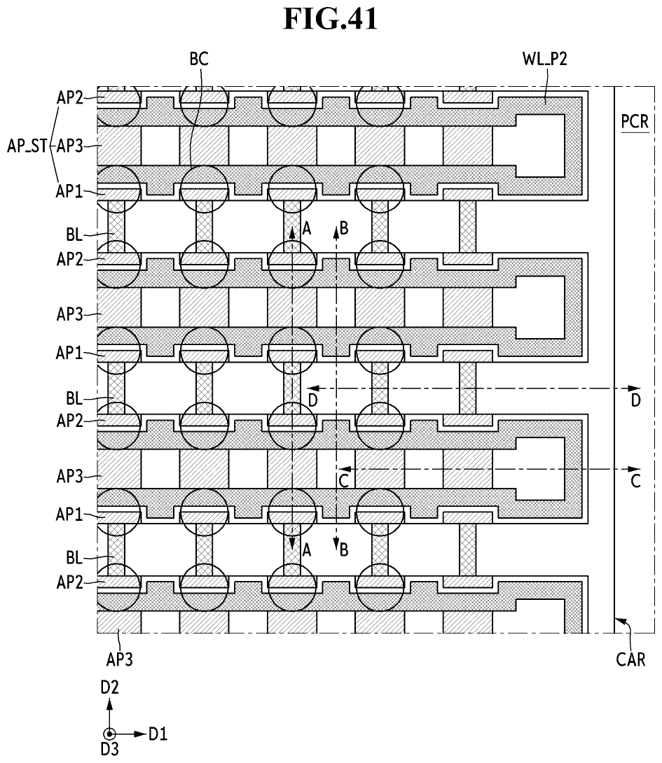

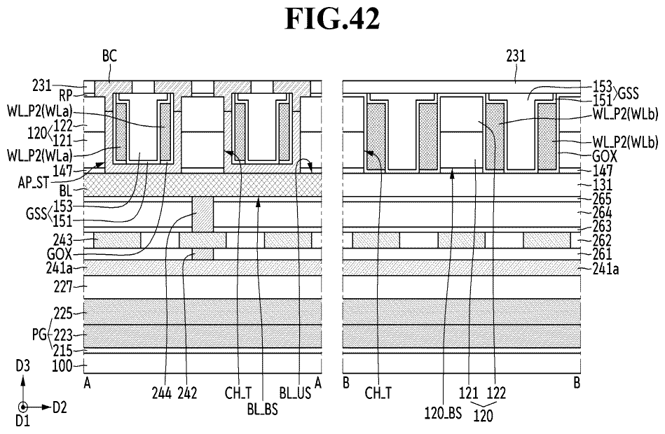

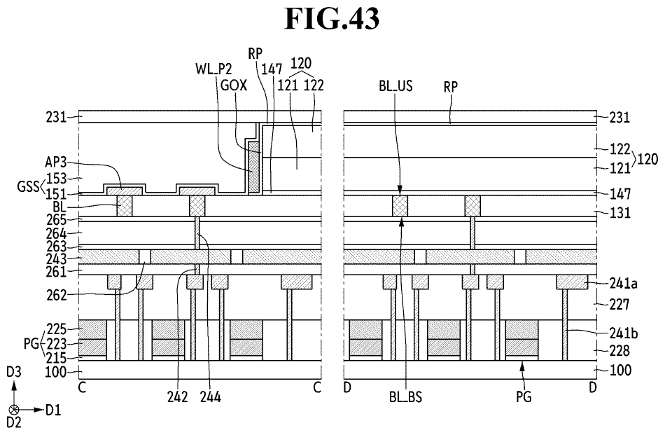

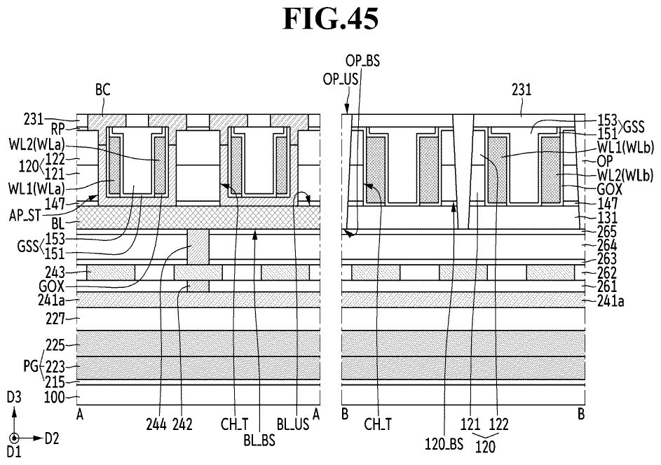

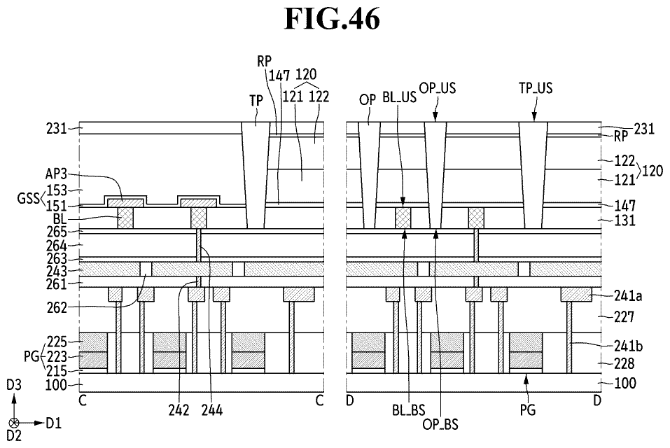

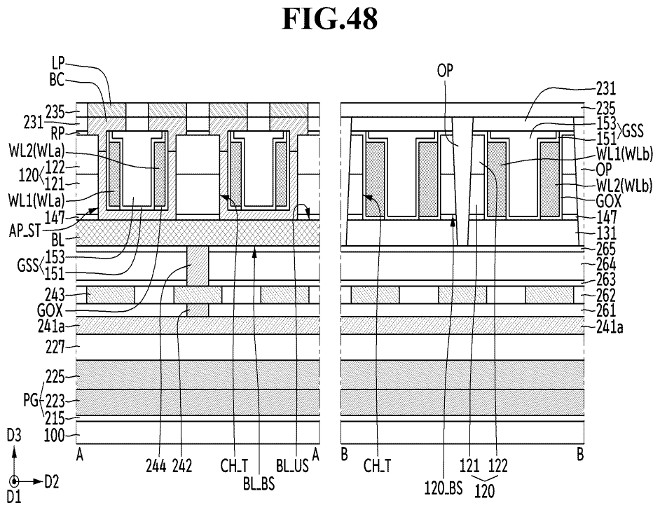

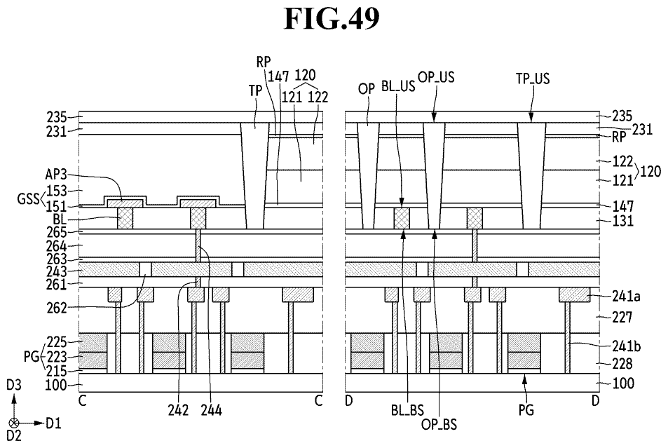

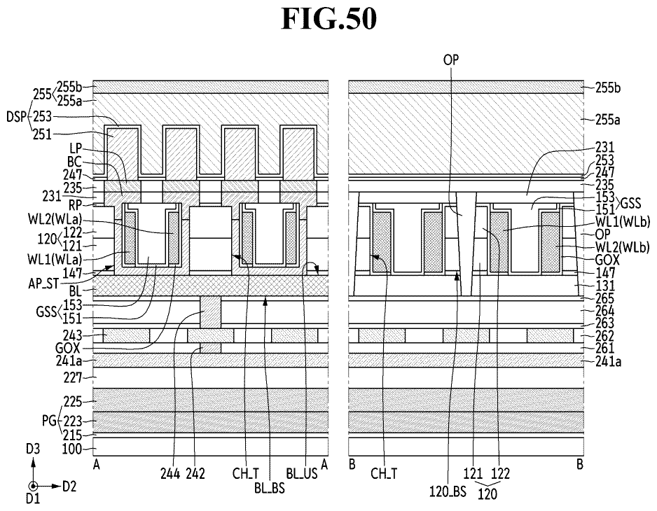

FIGS. 41 to 50 are views illustrating intermediate operations of a method for fabricating a semiconductor memory device according to some embodiments. For convenience of description, the description will be based on differences described with reference to FIGS. 20 to 40.

Referring to FIGS. 41 to 43, the contact isolation pattern 231 for at least partially exposing the upper surface of the channel structure AP_ST may be formed on the residual insulating film RP and the gate isolation pattern GSS.

Subsequently, the contact pattern BC may be formed between the contact isolation patterns 231. The contact pattern BC may be formed on the channel structure AP_ST. The contact pattern BC may be connected to the channel structure AP_ST.

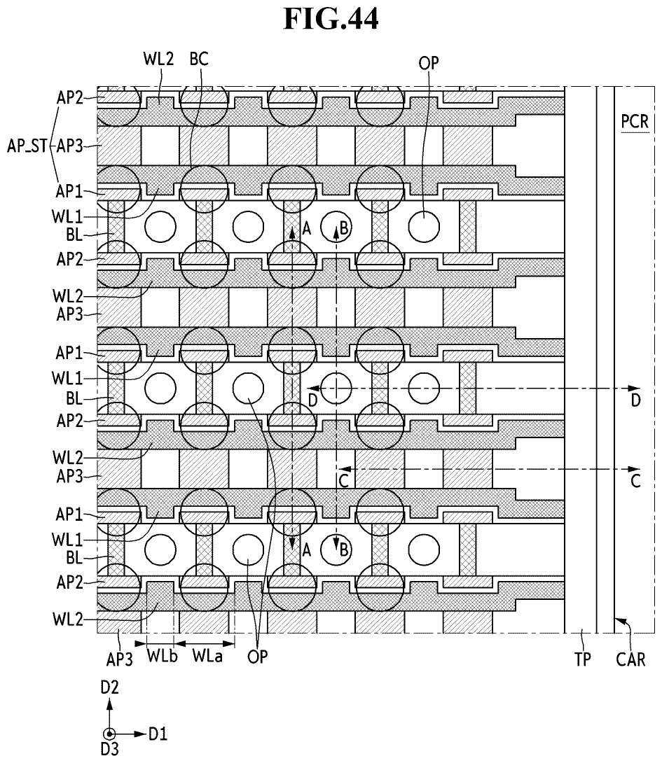

Referring to FIGS. 44 to 46, a pre-passage pattern and a pre-cutting pattern may be formed by passing through the contact isolation pattern 231 and the cell lower insulating layer 131.

In detail, the pre-cutting pattern may be formed by passing through the contact isolation pattern 231, the residual insulating film RP, the mold insulating structure layer 120, the gate isolation pattern GSS, the lower etching stop film 147, the gate insulating film GOX, the second pre-word line (see WL_P2 of FIG. 41) and the cell lower insulating layer 131. The pre-cutting pattern may be formed to be adjacent to the boundary between the cell array region CAR and the peripheral circuit region PCR in the second direction D2. The pre-cutting pattern may be extended along the second direction D2. The pre-cutting pattern may be formed by removing the third portion of the second pre-word line WL_P2. As a result, the second pre-word line WL_P2 may form the first word line WL1 and the second word line WL2.

Also, in detail, the pre-passage pattern may be formed by passing through the contact isolation pattern 231, the residual insulating film RP, the mold insulating structure layer 120, the lower etching stop film 147 and the cell lower insulating layer 131. The pre-passage pattern may be formed between the bit lines BL adjacent to each other in the first direction D1. The pre-passage pattern may be formed between the second portion WL_b of the first word line WL1 and the second portion WL_b of the second word line WL2, which are adjacent to each other in the second direction D2. In the semiconductor memory device according to some embodiments, the upper surface OP_US of the passage pattern OP and the upper surface TP_US of the cutting pattern TP may be formed to have the same height in the D3 direction as each other based on the bottom surface BL_BS of the bit line BL.

Subsequently, the pre-cutting pattern and the pre-passage pattern may be at least partially filled with an oxide-based material to form the cutting pattern TP and the passage pattern OP, respectively. The oxide-based material may contain, for example, silicon oxide.

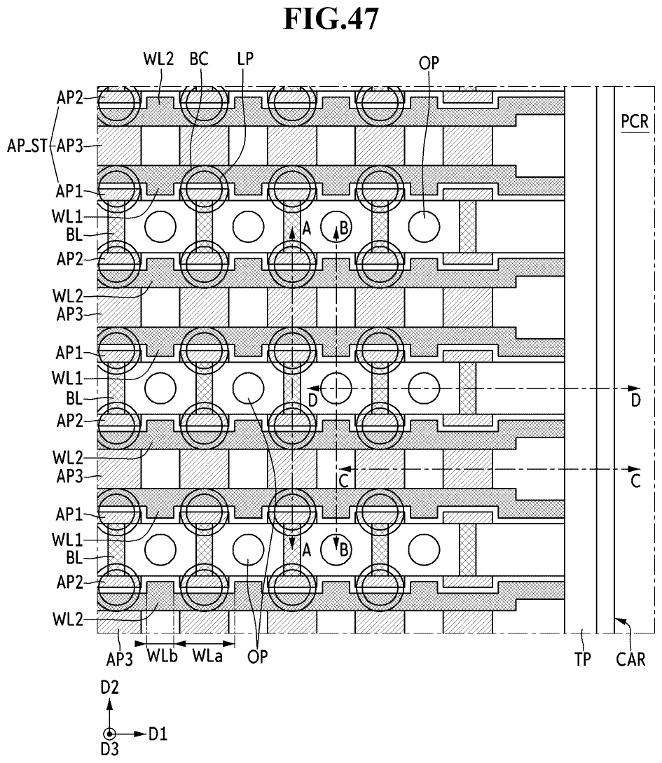

Referring to FIGS. 47 to 50, the pad isolation pattern 235 for exposing the upper surface of the contact pattern BC may be formed on the contact isolation pattern 231, the passage pattern OP and the cutting pattern TP.

In detail, the pad isolation pattern 235 may be formed to be in contact with the upper surface of the contact isolation pattern 231, the upper surface OP_US of the passage pattern OP, and the upper surface TP_US of the cutting pattern TP.

Subsequently, the landing pad LP may be formed between the pad isolation patterns 235. The landing pad LP may be formed on the contact pattern BC. The landing pad LP may be electrically connected to the contact pattern BC.

Subsequently, the data storage patterns DSP may be formed on the landing pad LP and the pad isolation pattern 235.

Subsequently, referring to FIGS. 2, 14 and 15, the cell upper insulating layer 480 and the upper wiring structure 450 may be formed on the data storage pattern DSP. Subsequently, the contact via CV for connecting the upper wiring structure 450 with the first peripheral wiring line 241a may be formed.

Although embodiments of the present disclosure have been described with reference to the accompanying drawings, the present disclosure is not limited to the above embodiments but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor memory device comprising:
a peripheral gate structure on a substrate;
a cell lower insulating layer on the peripheral gate structure;
a bit line in the cell lower insulating layer and extended in a first direction;
a mold insulating structure layer on the bit line and the cell lower insulating layer, including a channel trench extended in a second direction crossing the first direction;
a channel structure in the channel trench and electrically connected to an upper surface of the bit line, including a metal oxide;
a first word line on the channel structure and extended in the second direction;
a second word line on the channel structure, extended in the second direction, and spaced apart from the first word line in the first direction;
a cutting pattern that contacts an end of each of the first and second word lines and extended in the first direction;
a passage pattern in the mold insulating structure layer and including an oxide-based insulating material;
a pad isolation pattern on the mold insulating layer and the passage pattern and connected to the passage pattern;
a landing pad disposed in the pad isolation pattern and electrically connected to the channel structure; and
a data storage pattern on the landing pad.

2. The semiconductor memory device of claim 1, wherein an upper surface of the passage pattern is higher than an upper surface of the cutting pattern where an upper surface of the substrate provides a base reference plane.

3. The semiconductor memory device of claim 2, further comprising:
a contact isolation pattern between the mold insulating structure layer and the pad isolation pattern; and
a contact pattern in the contact isolation pattern and between the channel structure and the landing pad,
wherein the passage pattern contacts the pad isolation pattern by passing through the contact isolation pattern.

4. The semiconductor memory device of claim 2, wherein a bottom surface of the passage pattern is higher than a bottom surface of the mold insulating structure layer where the upper surface of the substrate provides a base reference plane.

5. The semiconductor memory device of claim 1, further comprising a lower etching stop film between the mold insulating structure layer and the cell lower insulating layer,
wherein the passage pattern contacts the cell lower insulating layer.

6. The semiconductor memory device of claim 5, further comprising:
a contact isolation pattern between the mold insulating structure layer and the pad isolation pattern; and
a contact pattern in the contact isolation pattern and between the channel structure and the landing pad,
wherein the cutting pattern and the passage pattern contact the pad isolation pattern by passing through the contact isolation pattern.

7. The semiconductor memory device of claim 5, wherein the passage pattern and the cutting pattern comprise a same material.

8. The semiconductor memory device of claim 1, further comprising a lower etching stop film between the mold insulating structure layer and the cell lower insulating layer,
wherein the mold insulating structure layer includes a first mold insulating layer on the lower etching stop film, and
a second mold insulating layer on the first mold insulating layer.

9. The semiconductor memory device of claim 8, wherein the first mold insulating layer includes an oxide-based insulating material, and
wherein the second mold insulating layer includes a nitride-based insulating material.

10. The semiconductor memory device of claim 1, further comprising:
a cell upper insulating layer on the data storage pattern, including an oxide-based insulating material; and
an upper wiring structure electrically connected to the data storage pattern and being in the cell upper insulating layer.

11. A semiconductor memory device comprising:
a peripheral gate structure on a substrate;
a cell lower insulating layer on the peripheral gate structure;
a bit line in the cell lower insulating layer and extended in a first direction;
a mold insulating structure layer on the bit line and the cell lower insulating layer, including a channel trench extended in a second direction crossing the first direction;
a channel structure in the channel trench and electrically connected to an upper surface of the bit line, the channel structure including a metal oxide;
a first word line on the channel structure and extended in the second direction;
a second word line on the channel structure, extended in the second direction, and spaced apart from the first word line in the first direction;
a contact isolation pattern on the mold insulating structure layer;
a contact pattern in the contact isolation pattern and electrically connected to the channel structure;
a pad isolation pattern on the contact isolation pattern and the contact pattern;
a landing pad in the pad isolation pattern and electrically connected to the contact pattern;
a passage pattern extended in a third direction crossing the first and second directions, passing through the contact isolation pattern and the pad isolation pattern;
a cutting pattern contacting an end of each of the first and second word lines, extended in the first direction;
an upper etching stop film on the landing pad and the pad isolation pattern, at least partially covering an upper surface of the passage pattern; and
a data storage pattern on the upper etching stop film and connected to the landing pad.

12. The semiconductor memory device of claim 11, further comprising a lower etching stop film between the mold insulating structure layer and the cell lower insulating layer,
wherein the mold insulating structure layer includes:
a first mold insulating layer on the lower etching stop film, and
a second mold insulating layer on the first mold insulating layer.

13. The semiconductor memory device of claim 12, wherein the first mold insulating layer includes an oxide-based insulating material, and
wherein the second mold insulating layer includes a nitride-based insulating material.

14. The semiconductor memory device of claim 11, wherein the passage pattern contacts the cell lower insulating layer.

15. The semiconductor memory device of claim 11, wherein the cutting pattern passes through the mold insulating structure layer, and contacts the cell lower insulating layer.

16. The semiconductor memory device of claim 11, further comprising:
a gate insulating film between the channel structure and the first and second word lines; and
a residual insulating film between the mold insulating structure layer and the contact isolation pattern, the residual insulating film and the gate insulating film comprising a same material,
wherein the passage pattern passes through the residual insulating film.

17. The semiconductor memory device of claim 11, wherein a width of the passage pattern narrows with decreasing distance from to the bit line in the third direction, and
wherein a width of the cutting pattern narrows with decreasing distance from the bit line in the third direction.

18. A semiconductor memory device comprising:
a peripheral gate structure on a substrate;
a cell lower insulating layer on the peripheral gate structure;
a plurality of bit lines in the cell lower insulating layer, extended in a first direction and arranged in a second direction crossing the first direction;
a mold insulating structure layer on the plurality of bit lines and the cell lower insulating layer, including a channel trench extended in the second direction;
a channel structure in the channel trench and electrically connected to an upper surface of the plurality of bit lines, containing metal oxide;
a first word line on the channel structure and extended in the second direction;
a second word line on the channel structure, extended in the second direction, and spaced apart from the first word line in the first direction;
a passage pattern between the respective bit lines adjacent to each other in the second direction and in the mold insulating structure layer;
a cutting pattern that contacts an end of each of the first and second word lines, extended in the first direction;
a landing pad on the channel structure and electrically connected to the channel structure;
an upper etching stop film on the landing pad and at least partially covering an upper surface of the passage pattern; and
a data storage pattern on the upper etching stop film and electrically connected to the landing pad.

19. The semiconductor memory device of claim 18, wherein the upper surface of the passage pattern is higher than an upper surface of the cutting pattern where an upper surface of the substrate provides a base reference plane.

20. The semiconductor memory device of claim 18, wherein the passage pattern and the channel structure do not overlap each other in the second direction.
